(19) United States
(12) Patent Application Publication
(10) Pub. No.: US 2024/0110272 A1
(43) Pub. Date: Apr. 4, 2024

(54) MASK ASSEMBLY AND METHOD OF MANUFACTURING THE SAME

(71) Applicant: Samsung Display Co., Ltd., Yongin-si (KR)

(72) Inventors: HEEMIN PARK, Yongin-si (KR); ARONG KIM, Yongin-si (KR); YOUNGMIN MOON, Yongin-si (KR); YOUNGHO PARK, Yongin-si (KR); AREUM LEE, Yongin-si (KR); SUNGSOON IM, Yongin-si (KR); JUNHO JO, Yongin-si (KR)

(73) Assignee: Samsung Display Co., Ltd., Yongin-si (KR)

(21) Appl. No.: 18/340,329

(22) Filed: Jun. 23, 2023

(30) Foreign Application Priority Data
Sep. 22, 2022 (KR) 10-2022-0120317

(51) Int. Cl. C23C 14/04

(52) U.S. Cl. CPC C23C 14/042

(57) ABSTRACT

A mask assembly includes an open mask including first and second open openings defined therethrough and alternately arranged in a first direction, first unit masks respectively corresponding to the first open openings, and second unit masks respectively corresponding to the second open openings. Each of the first unit masks includes a first deposition portion through which first deposition openings are defined and first and second welding portions extending from the first deposition portion to the first direction and a direction opposite to the first direction, respectively. Each of the second unit masks includes a second deposition portion through which second deposition openings are defined and third and fourth welding portions extending from the second deposition portion to a second direction and a direction opposite to the second direction.

### CROSS-REFERENCE TO RELATED APPLICATION(S)

This U.S. non-provisional patent application claims priority to and benefits of Korean Patent Application No. 10-2022-0120317 under 35 U.S.C. § 119, filed on Sep. 22, 2022 in the Korean Intellectual Property Office, the entire contents of which are incorporated herein by reference.

### BACKGROUND

### 1. Technical Field

The disclosure relates to a mask assembly with improved deposition precision and a method of manufacturing the mask assembly.

### 2. Description of the Related Art

In general, a light emitting display device includes pixels and light emitting elements respectively disposed in the pixels. Each light emitting element may include a light emitting layer disposed between two electrodes. The light emitting layers included in the pixels may be grouped into multiple groups.

A mask assembly may be used to deposit the light emitting layers on a work substrate. The mask assembly may include a frame, an open mask, and a mask provided in a unit of a cell. Patterned light emitting layers may be formed by placing the work substrate on the mask and depositing a light emitting material on the work substrate.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a mask assembly capable of reducing a shadow area during a deposition process to improve a deposition precision.

The disclosure provides a method of manufacturing the mask assembly with improved deposition precision.

Embodiments provide a mask assembly that may include an open mask including first open openings and second open openings, which are defined through the open mask and alternately arranged in a first direction, first unit masks respectively corresponding to the first open openings, and second unit masks respectively corresponding to the second open openings. Each of the first unit masks may include a first deposition portion including first deposition openings defined therethrough to overlap a corresponding first open opening among the first open openings, a first welding portion extending from the first deposition portion to the first direction and coupled with the open mask, and a second welding portion extending from the first deposition portion to a direction opposite to the first direction and coupled with the open mask. Each of the second unit masks may include a second deposition portion including second deposition openings defined therethrough to overlap a corresponding second open opening among the second open openings, a third welding portion extending from the second deposition portion to a second direction perpendicular to the first direction and coupled with the open mask, and a fourth welding portion extending from the second deposition portion to a direction opposite to the second direction and coupled with the open mask.

Each of the first welding portion and the second welding portion may not overlap the third welding portion and the fourth welding portion when viewed in the first direction.

A length in the first direction of each of the first unit masks may be greater than a length in the first direction of each of the second unit masks.

A length in the second direction of each of the second unit masks may be greater than a length in the second direction of each of the first unit masks.

The first open openings and the second open openings may be alternately arranged with each other in the second direction.

Each of the third and fourth welding portions may not overlap the first and second welding portions when viewed in the second direction.

The mask assembly may further include first welding protrusions arranged on the first welding portion of each of the first unit masks in the second direction, second welding protrusions arranged on the second welding portion of each of the first unit masks in the second direction, third welding protrusions arranged on the third welding portion of each of the second unit masks in the first direction, and fourth welding protrusions arranged on the fourth welding portion of each of the second unit masks in the first direction.

A minimum separation distance between the first welding protrusions and the first deposition openings in one first unit mask among the first unit masks may be equal to or greater than about 7.5 mm in plan view.

A minimum separation distance between the third welding protrusions and the second deposition openings in one second unit mask among the second unit masks may be equal to or greater than about 7.5 mm in plan view.

One of the first and second welding protrusions may be disposed between the first and second open openings adjacent to each other in the first direction among the first and second open openings in plan view, and one of the third and fourth welding protrusions may be disposed between the first and second open openings adjacent to each other in the second direction among the first and second open openings in plan view.

The first open openings and the second open openings may include a same shape as each other.

The first deposition portion of each of the first unit masks may include dummy deposition openings defined therethrough to overlap the open mask and surrounding the first deposition openings.

Embodiments provide a method of manufacturing a mask assembly. The manufacturing method may include providing an open mask through which first and second open openings are defined, placing a first unit mask through which first deposition openings are defined on the open mask to allow the first deposition openings to overlap the first open opening, coupling the first unit mask with the open mask, placing a second unit mask through which second deposition openings are defined on the open mask to allow the second deposition openings to overlap the second open opening, and coupling the second unit mask with the open mask. The first unit mask may be tensioned in a first direction and a direction opposite to the first direction in the placing of the first unit mask, and the second unit mask may be tensioned in a second direction perpendicular to the first direction and a direction opposite to the second direction in the placing of the second unit mask.

The first unit mask may be tensioned using a tensioner operated in a first mode in the placing of the first unit mask, and the second unit mask may be tensioned using the tensioner operated in a second mode in the placing of the second unit mask.

The tensioner may include a first group chuck including first porous chucks arranged in the second direction and second porous chucks spaced apart from the first porous chucks in the first direction and arranged in the second direction and a second group chuck including third porous chucks arranged in the first direction and fourth porous chucks spaced apart from the third porous chucks in the second direction and arranged in the first direction. The first group chuck may be in contact with the first unit mask to operate in the first mode, and the second group chuck may be in contact with the second unit mask to operate in the second mode.

The second group chuck may be spaced apart from the first unit mask in the first mode, and the first group chuck may be spaced apart from the second unit mask in the second mode.

In the placing of the first unit mask, the first unit mask may include a first deposition portion including the first deposition openings, a first protruding portion including a first welding portion extending from the first deposition portion to the first direction and a first tension portion extending from the first welding portion to the first direction, and a second protruding portion including a second welding portion extending from the first deposition portion to the direction opposite to the first direction and a second tension portion extending from the second welding portion to the direction opposite to the first direction. The tensioner may be disposed on the first and second tension portions.

In the coupling of the first unit mask, first welding protrusions arranged in the second direction may be formed on the first welding portion, and second welding protrusions arranged in the second direction may be formed on the second welding portion.

The method may further include cutting the first unit mask to remove the first and second tension portions after the coupling of the first unit mask and before the placing of the second unit mask.

Each of the first and second open openings may be provided in plural, and the plurality of first open openings may be alternately arranged with the plurality of second open openings in each of the first and second directions.

According to the above, the separation distance between the welding protrusions, which may be formed while coupling the open mask and the unit mask, and the deposition opening of the unit mask through which the deposition material passes may be designed to be apart from each other. Thus, in case that a deposition process is carried out on a light emitting layer of a display panel using the mask assembly, an adhesion between a base substrate that is a deposition target and the unit mask may be improved, and thus, a deposition precision may be enhanced. Accordingly, a display quality of the display panel may be improved.

### BRIEF DESCRIPTION OF THE DRAWINGS

The above and other advantages of the disclosure will become readily apparent by reference to the following detailed description when considered in conjunction with the accompanying drawings wherein:

FIG. 1 is a schematic cross-sectional view of a deposition apparatus according to an embodiment of the disclosure;

FIG. 2 is an exploded schematic perspective view of a mask assembly according to an embodiment of the disclosure;

FIGS. 3A and 3B are enlarged schematic plan views of some components of a mask assembly according to an embodiment of the disclosure;

FIG. 4 is a schematic cross-sectional view of the mask assembly taken along a line I-I′ of FIG. 3B;

FIGS. 5A and 5B are schematic perspective views of a method of manufacturing a mask assembly according to an embodiment of the disclosure;

FIG. 5C is an enlarged schematic cross-sectional view of a tensioner used to manufacture the mask assembly according to an embodiment of the disclosure;

FIG. 5D is an enlarged schematic plan view of a tensioner used to manufacture the mask assembly according to an embodiment of the disclosure;

FIGS. 5E to 5H are schematic cross-sectional views of the manufacturing method of the mask assembly according to an embodiment of the disclosure;

FIG. 51 is a schematic perspective view of the manufacturing method of the mask assembly according to an embodiment of the disclosure;

FIG. 6A is a schematic perspective view of the manufacturing method of the mask assembly according to an embodiment of the disclosure;

FIGS. 6B to 6E are schematic cross-sectional views of the manufacturing method of the mask assembly according to an embodiment of the disclosure;

FIGS. 6F and 6G are schematic perspective views of the manufacturing method of the mask assembly according to an embodiment of the disclosure; and

FIG. 7 is a schematic cross-sectional view of a display panel according to an embodiment of the disclosure.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components may be exaggerated for effective description of the technical content.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

It will be understood that, although the terms first, second, etc. may be used herein to describe various elements, these elements should not be limited by these terms. These terms are only used to distinguish one element from another element. Thus, a first element discussed below could be termed a second element without departing from the teachings of the disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or to “not overlap” another element, this may include that the elements are spaced apart from each other, offset from each other, or set aside from each other or any other suitable term as would be appreciated and understood by those of ordinary skill in the art.

“About” or “approximately” or “substantially” as used herein are inclusive of the stated value and mean within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

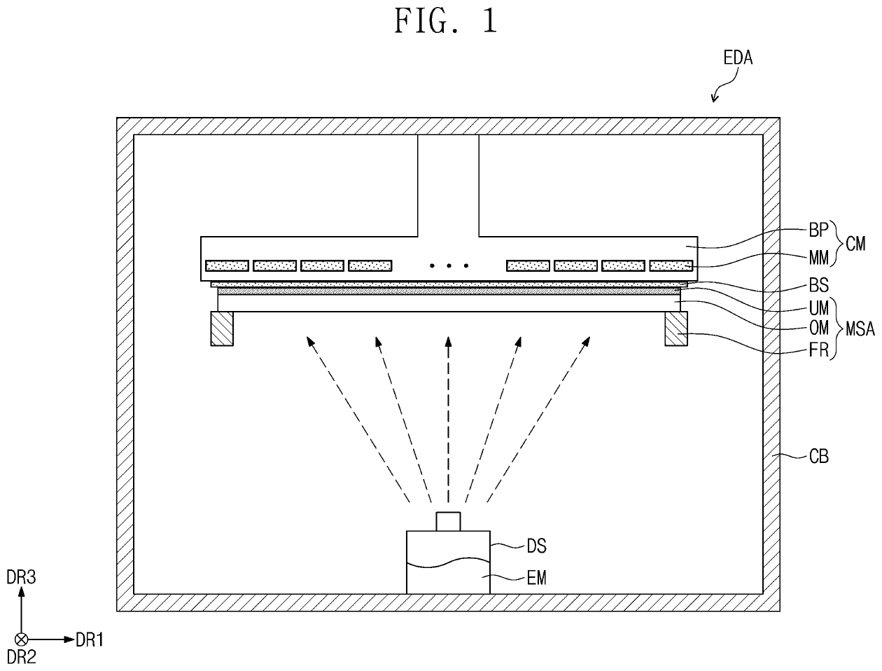

FIG. 1 is a schematic cross-sectional view of a deposition apparatus EDA according to an embodiment of the disclosure.

Referring to FIG. 1, the deposition apparatus EDA may include a deposition chamber CB, a fixing member CM, a deposition source DS disposed in the deposition chamber CB, and a mask assembly MSA disposed in the deposition chamber CB. Although not shown in FIG. 1, the deposition apparatus EDA may further include additional mechanical apparatus to implement an inline system.

The deposition chamber CB may set a deposition condition to a vacuum state. The deposition chamber CB may include a bottom surface, a ceiling surface, and sidewalls. The bottom surface of the deposition chamber CB may be substantially parallel to a plane defined by a first direction DR1 and a second direction DR2. A third direction DR3 may indicate a normal line direction of the bottom surface of the deposition chamber CB.

The fixing member CM may be disposed in the deposition chamber CB, may be disposed on the deposition source DS, and may fix the mask assembly MSA. The fixing member CM may be installed at the ceiling surface of the deposition chamber CB. The fixing member CM may include a jig or a robot arm to hold the mask assembly MSA.

The fixing member CM may include a body portion BP and magnetic substances MM coupled to the body portion BP. The body portion BP may include a plate as a basic structure to fix the mask assembly MSA, however, it should not be particularly limited. The magnetic substances MM may be disposed inside or outside of the body portion BP. The magnetic substances MM may fix the mask assembly MSA using a magnetic force, and thus, a base substrate BS may be tightly adhered to the mask assembly MSA.

The deposition source DS may be used to evaporate a deposition material EM, e.g., a light emitting material, and to spray the evaporated deposition material as a vapor. The sprayed deposition material EM may be deposited on the base substrate BS in a predetermined or selected pattern after passing through the mask assembly MSA. The base substrate BS may correspond to a substrate in an intermediate stage of manufacturing a display panel DP described with reference to FIG. 7.

The mask assembly MSA may be disposed in the deposition chamber CB and may be disposed on the deposition source DS. The mask assembly MSA may support the base substrate BS disposed on the mask assembly MSA.

In an embodiment, the mask assembly MSA may include a frame FR, an open mask OM, and a unit mask UM. One unit mask UM may be a mask used to deposit one display panel DP in a unit of cell. This will be described in detail later.

The base substrate BS may be disposed between the mask assembly MSA and the fixing member CM. The base substrate BS may include a glass substrate or a plastic substrate. The base substrate BS may include a polymer layer disposed on the glass substrate or the plastic substrate. The base substrate BS may be provided as a base surface of a layer formed by the deposition apparatus EDA. Accordingly, the base substrate BS should not be particularly limited as long as the base substrate BS is a component of the display panel DP (refer to FIG. 7) and is disposed under a component, which is formed by a deposition process, of the display panel DP (refer to FIG. 7) described later. The base substrate BS may be removed from the display panel DP (refer to FIG. 7) after a manufacturing process of the display panel DP (refer to FIG. 7) is completed, however, it should not be particularly limited.

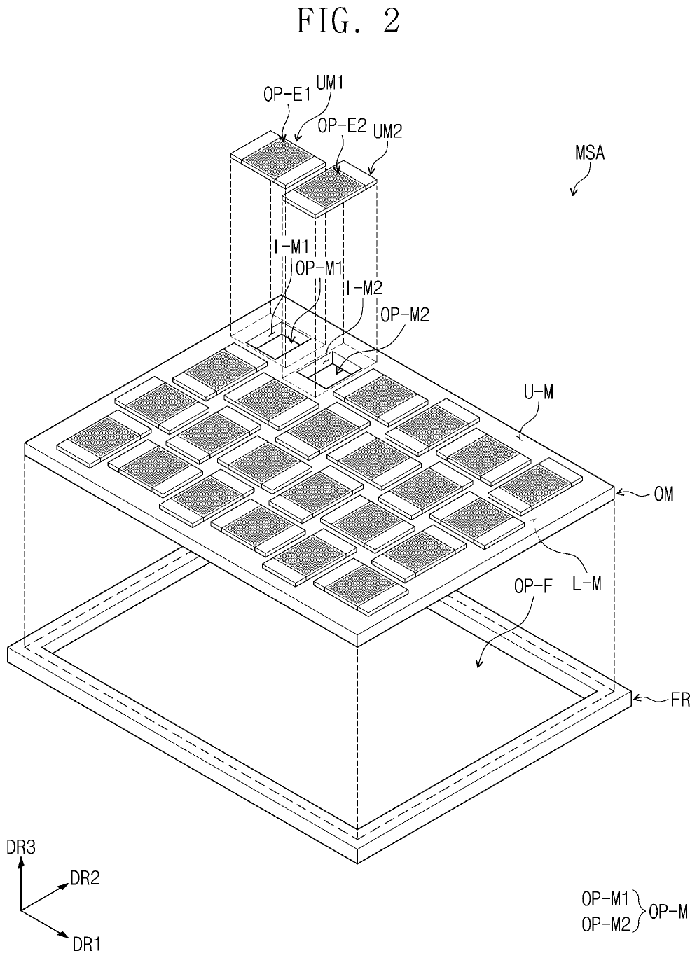

FIG. 2 is an exploded schematic perspective view of the mask assembly MSA according to an embodiment of the disclosure.

Referring to FIG. 2, the mask assembly MSA may include the frame FR, the open mask OM, first unit masks UM1, and second unit masks UM2. The unit mask UM of FIG. 1 may include the first unit masks UM1 and the second unit masks UM2.

The frame FR may be disposed under the open mask OM and may support the open mask OM, the first unit masks UM1, and the second unit masks UM2.

According to an embodiment, the frame FR may include sticks extending in the first direction DR1 and sticks extending in the second direction DR2. The sticks extending in the second direction DR2 may extend from both ends of the sticks extending in the first direction DR1, respectively. The sticks extending in the first direction DR1 and the sticks extending in the second direction DR2 may be consecutively provided to define a frame opening OP-F.

The deposition material EM (refer to FIG. 1) sprayed from the deposition source DS (refer to FIG. 1) may pass through openings defined through each of the open mask OM, the first unit masks UM1, and the second unit masks UM2 after passing through the frame opening OP-F.

In the disclosure, the frame FR through which one frame opening OP-F is defined is shown as a representative example, however, multiple frame openings OP-F may be defined through the frame FR, and one open mask OM may be supported by multiple frames FR.

The shape of the frame FR should not be particularly limited as long as the frame FR may support the open mask OM. The frame FR may be fixed to the sidewalls of the deposition chamber CB (refer to FIG. 1), and it should not be particularly limited.

The frame FR may include a metal material. The frame FR may include, for example, stainless steel (SUS), invar, nickel (Ni), an alloy of nickel and cobalt, an alloy of nickel and iron, and/or the like.

The open mask OM may be disposed on the frame FR. The open mask OM may include a lower surface L-M making contact with the frame FR and an upper surface U-M opposite to the lower surface L-M. The open mask OM may have a rectangular shape defined by sides extending in the first direction DR1 and sides extending in the second direction DR2.

Multiple open openings OP-M may be formed through the open mask OM by removing a portion of the open mask OM from the upper surface U-M to the lower surface L-M along the third direction DR3. FIG. 2 shows the open openings OP-M arranged in six rows by four columns as a representative example, however, the number and arrangement of the open openings OP-M should not be limited thereto or thereby.

In an embodiment, the open openings OP-M may include first open openings OP-M1 and second open openings OP-M2. The first open openings OP-M1 may be alternately arranged with the second open openings OP-M2 in the first direction DR1 and the second direction DR2. FIG. 2 shows one first open opening OP-M1 and one second open opening OP-M2 spaced apart from the first open opening OP-M1 in the first direction DR1 as a representative example.

The first and second open openings OP-M1 and OP-M2 may be arranged to overlap the frame opening OP-F. Accordingly, the deposition material EM (refer to FIG. 1) sprayed from the deposition source DS (refer to FIG. 1) may be provided to the first and second open openings OP-M1 and OP-M2 without being interfered with by the frame opening OP-F.

An inner side surface I-M1 of the open mask OM, which defines each of the first open openings OP-M1, may include short sides extending in the first direction DR1 and long sides extending from the short sides to the second direction DR2. An inner side surface I-M2 of the open mask OM, which defines each of the second open openings OP-M2, may include short sides extending in the first direction DR1 and long sides extending from the short sides to the second direction DR2.

In an embodiment, the first open openings OP-M1 and the second open openings OP-M2 may have the same shape as each other. Each of the first and second open openings OP-M1 and OP-M2 may have a rectangular shape or may have a quadrangular shape whose corners at which the long sides meet the short sides are rounded (or are curved at a predetermined or selected curvature) in plan view.

The open mask OM may include a metal material. The open mask OM may include, for example, stainless steel (SUS), invar, nickel (Ni), cobalt (Co), an alloy of nickel, an alloy of nickel and cobalt, and/or the like.

The first unit masks UM1 may be disposed on the open mask OM. The first unit masks UM1 may be disposed on the upper surface U-M of the open mask OM. The first unit masks UM1 may be arranged to respectively correspond to the first open openings OP-M1. For example, each of the first unit masks UM1 may be arranged to overlap a corresponding first open opening among the first open openings OP-M1.

The second unit masks UM2 may be disposed on the open mask OM. The second unit masks UM2 may be disposed on the upper surface U-M of the open mask OM. The second unit masks UM2 may be arranged to respectively correspond to the second open openings OP-M2. For example, each of the second unit masks UM2 may be arranged to overlap a corresponding second open opening among the second open openings OP-M2.

As the first unit masks UM1 and the second unit masks UM2 are arranged to overlap the first open openings OP-M1 and the second open openings OP-M2, respectively, the first unit masks UM1 and the second unit masks UM2 may be alternately arranged with each other in the first direction DR1 and the second direction DR2. According to an embodiment, open openings covered by the first unit masks UM1 among the open openings OP-M may be referred to as the first open openings OP-M1, and open openings covered by the second unit masks UM2 among the open openings OP-M may be referred to as the second open openings OP-M2.

Each of the first and second unit masks UM1 and UM2 may include a metal material. According to an embodiment, each of the first and second unit masks UM1 and UM2 may include, for example, stainless steel (SUS), invar, nickel (Ni), cobalt (Co), an alloy of nickel, an alloy of nickel and cobalt, and/or the like.

According to an embodiment, each of the first unit masks UM1 may include first deposition openings OP-E1. The first deposition openings OP-E1 of each of the first unit masks UM1 may be exposed through a corresponding first open opening OP-M1 without being covered by the open mask OM. Each of the second unit masks UM2 may include second deposition openings OP-E2. The second deposition openings OP-E2 of each of the second unit masks UM2 may be exposed through a corresponding second open opening OP-M2 without being covered by the open mask OM.

Accordingly, the deposition material EM (refer to FIG. 1) sprayed from the deposition source DS (refer to FIG. 1) may be provided to the first and second deposition openings OP-E1 and OP-E2 without being interfered with due to the first and second open openings OP-M1 and OP-M2. The deposition material EM (refer to FIG. 1) may be deposited on the base substrate BS (refer to FIG. 1) to form a deposition pattern corresponding to the first deposition openings OP-E1 or the second deposition openings OP-E2.

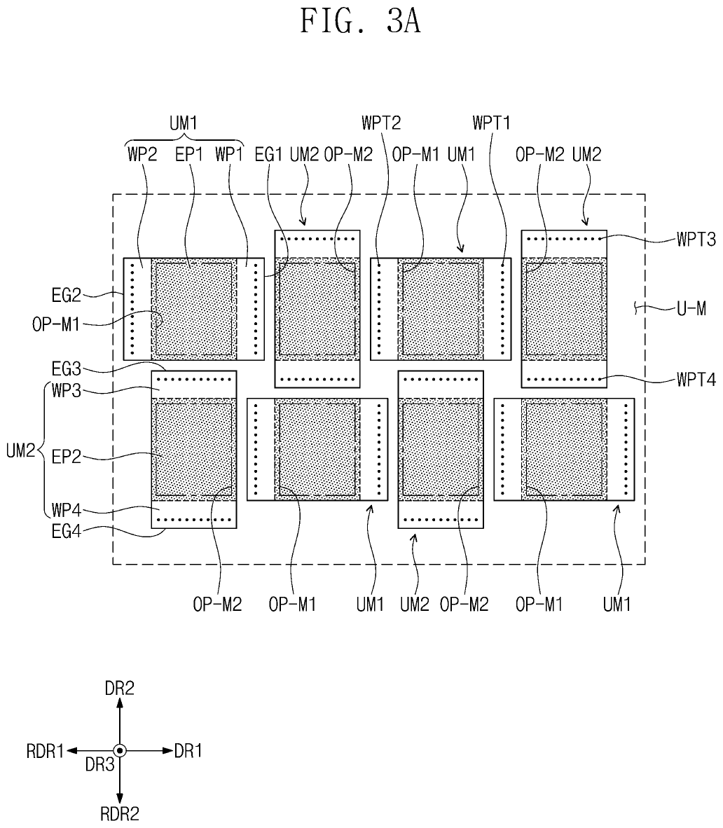

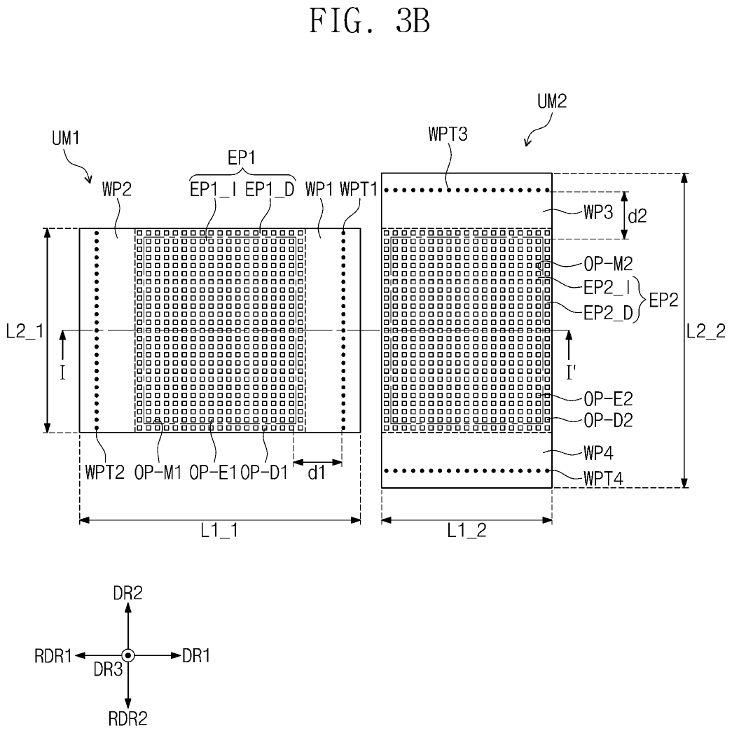

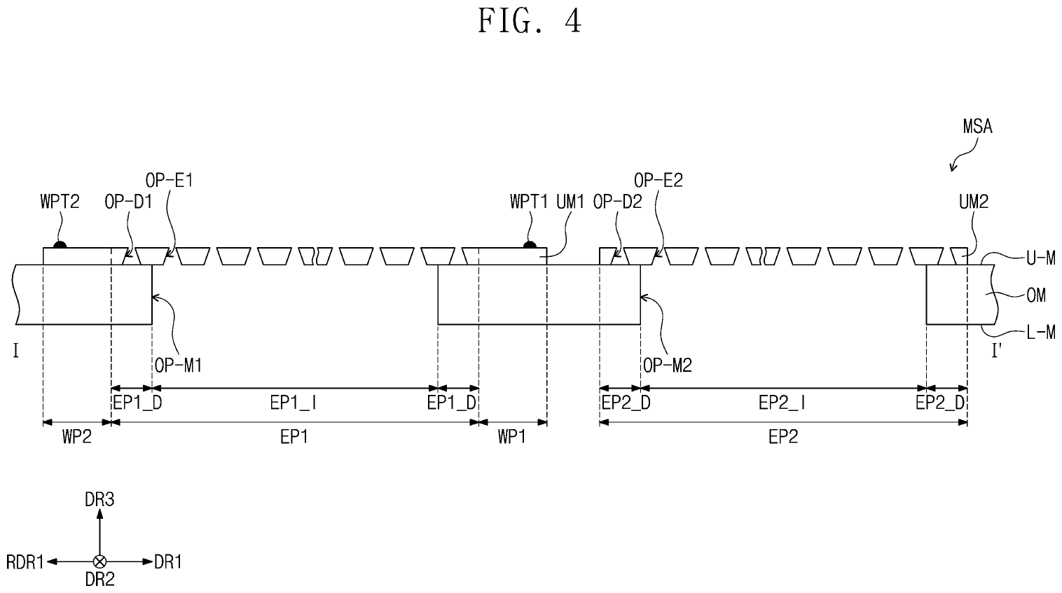

FIGS. 3A and 3B are enlarged schematic plan views of some components of the mask assembly according to an embodiment of the disclosure, and FIG. 4 is a schematic cross-sectional view of the mask assembly taken along a line I-I′ of FIG. 3B.

FIG. 3A shows the first and second unit masks UM1 and UM2 arranged in four rows by two columns among the first and second unit masks UM1 and UM2 alternately arranged with each other in the first direction DR1 and the second direction DR2 as a representative example. FIG. 3B is an enlarged plan view showing one first unit mask UM1 and one second unit mask UM2 adjacent to the one first unit mask UM1 in the first direction DR1. For the convenience of explanation, a boundary of the first open openings OP-M1 and a boundary of the second open openings OP-M2 are shown as a dash-single dotted line in FIGS. 3A and 3B. Hereinafter, the first unit masks UM1 and the second unit masks UM2 will be described in detail with reference to FIGS. 3A, 3B, and 4.

Each of the first unit masks UM1 may include a first deposition portion EP1, a first welding portion WP1, and a second welding portion WP2.

The first deposition portion EP1 may overlap a corresponding first open opening OP-M1. In an embodiment, as shown in FIGS. 3B and 4, the first deposition portion EP1 may include a first inner portion EP1_I and a first dummy portion EP1_D.

The first inner portion EP1_I may be a portion that overlaps the corresponding first open opening OP-M1. The first inner portion EP1_I may be provided with the first deposition openings OP-E1 defined therethrough. All of the first deposition openings OP-E1 may overlap the corresponding first open opening OP-M1.

The first dummy portion EP1_D may surround the first inner portion EP1_I. The first dummy portion EP1_D may not overlap the first open opening OP-M1 and may overlap the upper surface U-M of the open mask OM. The first dummy portion EP1_D may be provided with first deposition dummy openings OP-D1 defined therethrough. The first deposition dummy openings OP-D1 may surround the first deposition openings OP-E1. All of the first deposition dummy openings OP-D1 may overlap the upper surface U-M of the open mask OM.

Referring to FIG. 4, when viewed in a direction toward the lower surface L-M of the open mask OM, the first deposition openings OP-E1 may be exposed through the corresponding first open opening OP-M1 without being covered by the open mask OM, however, the first deposition dummy openings OP-D1 may be covered by the open mask OM and may not be exposed. Accordingly, the deposition material EM (refer to FIG. 1) sprayed from the deposition source DS (refer to FIG. 1) may pass through the first deposition openings OP-E1 but may not pass through the first deposition dummy openings OP-D1.

As shown in FIG. 3B, the first deposition dummy openings OP-D1 may have substantially the same shape and size as those of the first deposition openings OP-E1. In case that the first unit mask UM1 is patterned, an etching precision of outmost openings among the openings may be lower than an etching precision of openings placed at an inner side. According to an embodiment, as the first deposition dummy openings OP-D1 surrounding the outmost openings of the first deposition openings OP-E1 are provided, the first deposition openings OP-E1 placed at an inner side of the first deposition dummy openings OP-D1 may be provided with relatively high etching precision. Accordingly, a reliability of the first deposition openings OP-E1 may be improved.

FIG. 3B shows a structure in which the first deposition dummy openings OP-D1 are arranged in a line along the first deposition openings placed at an outer position among the first deposition openings OP-E1 as a representative example, however, the first deposition dummy openings OP-D1 may be arranged in multiple lines. According to an embodiment, the first deposition dummy openings OP-D1 may be omitted, and the first deposition portion EP1 may include only the first inner portion EP1_I.

The first welding portion WP1 may extend from the first deposition portion EP1 to the first direction DR1. The first welding portion WP1 may be coupled to the open mask OM.

The second welding portion WP2 may extend from the first deposition portion EP1 to a first opposite direction RDR1 opposite to the first direction DR1. The second welding portion WP2 may be spaced apart from the first welding portion WP1 with the first deposition portion EP1 interposed therebetween in the first direction DR1. The second welding portion WP2 may be coupled to the open mask OM.

Each of the second unit masks UM2 may include a second deposition portion EP2, a third welding portion WP3, and a fourth welding portion WP4.

The second deposition portion EP2 may overlap a corresponding second open opening OP-M2. In an embodiment, as shown in FIGS. 3B and 4, the second deposition portion EP2 may include a second inner portion EP2_I and a second dummy portion EP2_D.

The second inner portion EP2_I may overlap a corresponding second open opening OP-M2. The second inner portion EP2_I may be provided with second deposition openings OP-E2 defined therethrough. All of the second deposition openings OP-E2 may overlap the corresponding second open opening OP-M2.

The second dummy portion EP2_D may surround the second inner portion EP2_I. The second dummy portion EP2_D may not overlap the second open opening OP-M2 and may overlap the upper surface U-M of the open mask OM. The second dummy portion EP2_D may be provided with second deposition dummy openings OP-D2 defined therethrough. The second deposition dummy openings OP-D2 may surround the second deposition openings OP-E2. All of the second deposition dummy openings OP-D2 may overlap the upper surface U-M of the open mask OM.

Referring to FIG. 4, when viewed in the direction toward the lower surface L-M of the open mask OM, the second deposition openings OP-E2 may be exposed through the second open opening OP-M2 without being covered by the open mask OM, however, the second deposition dummy openings OP-D2 may be covered by the open mask OM without being exposed. Accordingly, the deposition material EM (refer to FIG. 1) sprayed from the deposition source DS (refer to FIG. 1) may pass through the second deposition openings OP-E2 but may not pass through the second deposition dummy openings OP-D2.

As shown in FIG. 3B, the second deposition dummy openings OP-D2 may have substantially the same shape and size as those of the second deposition openings OP-E2. Similar to the first deposition dummy openings OP-D1, as the second deposition dummy openings OP-D2 are provided to the second deposition portion EP2, the second deposition openings OP-E2 placed at an inner side of the second deposition dummy openings OP-D2 may be provided with relatively high etching precision. Accordingly, a reliability of the second deposition openings OP-E2 may be improved.

FIG. 3B shows a structure in which the second deposition dummy openings OP-D2 are arranged in a line along the second deposition openings placed at an outer position among the second deposition openings OP-E2 as a representative example, however, the second deposition dummy openings OP-D2 may be arranged in multiple lines. According to an embodiment, the second deposition dummy openings OP-D2 may be omitted, and the second deposition portion EP2 may include only the second inner portion EP2_I.

The third welding portion WP3 may extend from the second deposition portion EP2 to the second direction DR2. The third welding portion WP3 may be coupled to the open mask OM.

The fourth welding portion WP4 may extend from the second deposition portion EP2 to a second opposite direction RDR2 opposite to the second direction DR2. The fourth welding portion WP4 may be spaced apart from the third welding portion WP3 with the second deposition portion EP2 interposed therebetween in the second direction DR2. The fourth welding portion WP4 may be coupled to the open mask OM.

According to an embodiment, the first deposition portion EP1 and the second deposition portion EP2 may have substantially the same shape and size as each other. Accordingly, the first unit mask UM1 may include the first and second welding portions WP1 and WP2 extending from the first deposition portion EP1 to the first direction DR1 and the first opposite direction RDR1, respectively, and the second unit mask UM2 may include the third and fourth welding portions WP3 and WP4 extending from the second deposition portion EP2 to the second direction DR2 and the second opposite direction RDR2, respectively. Accordingly, a length L1_1 in the first direction DR1 of the first unit mask UM1 may be greater than a length L1_2 in the first direction DR1 of the second unit mask UM2. Similarly, a length L2_2 in the second direction DR2 of the second unit mask UM2 may be greater than a length L2_1 in the second direction DR2 of the first unit mask UM1.

As shown in FIG. 3A, at least one of an edge EG1 of the first welding portion WP1 and an edge EG2 of the second welding portion WP2 may be arranged closer to the second open opening OP-M2 adjacent to the corresponding first open opening OP-M1 than the corresponding first open opening OP-M1 in plan view. The edge EG1 of the first welding portion WP1 may correspond to an edge of the first welding portion WP1 extending in the second direction DR2 and spaced apart from the first deposition portion EP1, and the edge EG2 of the second welding portion WP2 may correspond to an edge of the second welding portion WP2 extending in the second direction DR2 and spaced apart from the first deposition portion EP1.

Similarly, at least one of an edge EG3 of the third welding portion WP3 and an edge EG4 of the fourth welding portion WP4 may be arranged closer to the corresponding first open opening OP-M1 adjacent to the corresponding second open opening OP-M2 than the corresponding second open opening OP-M2. The edge EG3 of the third welding portion WP3 may correspond to an edge of the third welding portion WP3 extending in the first direction DR1 and spaced apart from the second deposition portion EP2, and the edge EG4 of the fourth welding portion WP4 may correspond to an edge of the fourth welding portion WP4 extending in the first direction DR1 and spaced apart from the second deposition portion EP2.

The disclosure should not be limited thereto or thereby. According to a process condition of tensioning and a process condition of trimming, a separation distance between the edges EG1 and EG2 of the first and second welding portions WP1 and WP2 and the corresponding first open opening OP-M1 may be equal to or smaller than a separation distance between the edges EG1 and EG2 of the first and second welding portions WP1 and WP2 and the second open opening OP-M2 adjacent thereto, and a separation distance between the edges EG3 and EG4 of the third and fourth welding portions WP3 and WP4 and the corresponding second open opening OP-M2 may be equal to or smaller than a separation distance between the edges EG3 and EG4 of the third and fourth welding portions WP3 and WP4 and the corresponding first open opening OP-M1.

According to an embodiment, when viewed in the first direction DR1, each of the first and second welding portions WP1 and WP2 may not overlap the third and fourth welding portions WP3 and WP4. When viewed in the second direction DR2, each of the third and fourth welding portions WP3 and WP4 may not overlap the first and second welding portions WP1 and WP2.

According to the disclosure, the mask assembly MSA may further include first, second, third, and fourth welding protrusions WPT1, WPT2, WPT3, and WPT4. The first, second, third, and fourth welding protrusions WPT1, WPT2, WPT3, and WPT4 may be generated during a welding process performed on the first and second unit masks UM1 and UM2 to attach the open mask OM to the first and second unit masks UM1 and UM2.

The first welding protrusions WPT1 may be disposed on the first welding portion WP1 of the corresponding first unit mask UM1. The first welding protrusions WPT1 may be arranged in the second direction DR2 on the first welding portion WP1 of the corresponding first unit mask UM1. The first welding protrusions WPT1 may be arranged adjacent to the edge EG1 of the first welding portion WP1 of the corresponding first unit mask UM1.

The second welding protrusions WPT2 may be disposed on the second welding portion WP2 of the corresponding first unit mask UM1. The second welding protrusions WPT2 may be arranged in the second direction DR2 on the second welding portion WP2 of the corresponding first unit mask UM1. The second welding protrusions WPT2 may be arranged adjacent to the edge EG2 of the second welding portion WP2 of the corresponding first unit mask UM1.

The third welding protrusions WPT3 may be disposed on the third welding portion WP3 of the corresponding second unit mask UM2. The third welding protrusions WPT3 may be arranged in the first direction DR1 on the third welding portion WP3 of the corresponding second unit mask UM2. The third welding protrusions WPT3 may be arranged adjacent to the edge EG3 of the third welding portion WP3 of the corresponding second unit mask UM2.

The fourth welding protrusions WPT4 may be disposed on the fourth welding portion WP4 of the corresponding second unit mask UM2. The fourth welding protrusions WPT4 may be arranged in the first direction DR1 on the fourth welding portion WP4 of the corresponding second unit mask UM2. The fourth welding protrusions WPT4 may be arranged adjacent to the edge EG4 of the fourth welding portion WP4 of the corresponding second unit mask UM2.

In an embodiment, when viewed in the first direction DR1, each of the first and second welding protrusions WPT1 and WPT2 may be spaced apart from the third and fourth welding protrusions WPT3 and WPT4, and when viewed in the second direction DR2, each of the third and fourth welding protrusions WPT3 and WPT4 may be spaced apart from the first and second welding protrusions WPT1 and WPT2.

In plan view, one of the first and second welding protrusions WPT1 and WPT2 may be disposed between the first open opening OP-M1 and the second open opening OP-M2 adjacent to the first open opening OP-M1 in the first direction DR1 among the first open openings OP-M1 and the second open openings OP-M2. In plan view, one of the third and fourth welding protrusions WPT3 and WPT4 may be disposed between the first open opening OP-M1 and the second open opening OP-M2 adjacent to the first open opening OP-M1 in the second direction DR2 among the first open openings OP-M1 and the second open openings OP-M2.

Different from the disclosure, in a case where a direction in which the first and second welding portions WP1 and WP2 extend from the first deposition portion EP1 and a direction in which the third and fourth welding portions WP3 and WP4 extend from the second deposition portion EP2 are the same as each other and correspond to one direction, one of the first and second welding portions WP1 and WP2 and one of the third and fourth welding portions WP3 and WP4 may be placed together in a space between the first and second open openings OP-M1 and OP-M2 adjacent to each other of the open mask OM in the one direction, and thus, an area occupied by one unit mask UM1 or UM2 may be relatively small.

One of the first and second welding protrusions WPT1 and WPT2 disposed on the first unit mask UM1 and one of the third and fourth welding protrusions WPT3 and WPT4 disposed on the second unit mask UM2 may be placed together in the space between the first and second open openings OP-M1 and OP-M2 adjacent to each other in the one direction, and thus, a distance between one welding protrusion and deposition openings of one unit mask may be relatively short.

On the other hand, according to the disclosure, as the mask assembly MSA includes the first unit mask UM1 including the first and second welding portions WP1 and WP2 extending from the first deposition portion EP1 to the first direction DR1 and the first opposite direction RDR1, respectively, and the second unit mask UM2 including the third and fourth welding portions WP3 and WP4 extending from the second deposition portion EP2 to the second direction DR2 and the second opposite direction RDR2, respectively, and the first unit masks UM1 and the second unit masks UM2 are alternately arranged with each other in the first direction DR1 and the second direction DR2, the welding portion of only one unit mask of the first and second unit masks UM1 and UM2 may be disposed in the space between the first open opening OP-M1 and the second open opening OP-M2 of the open mask OM.

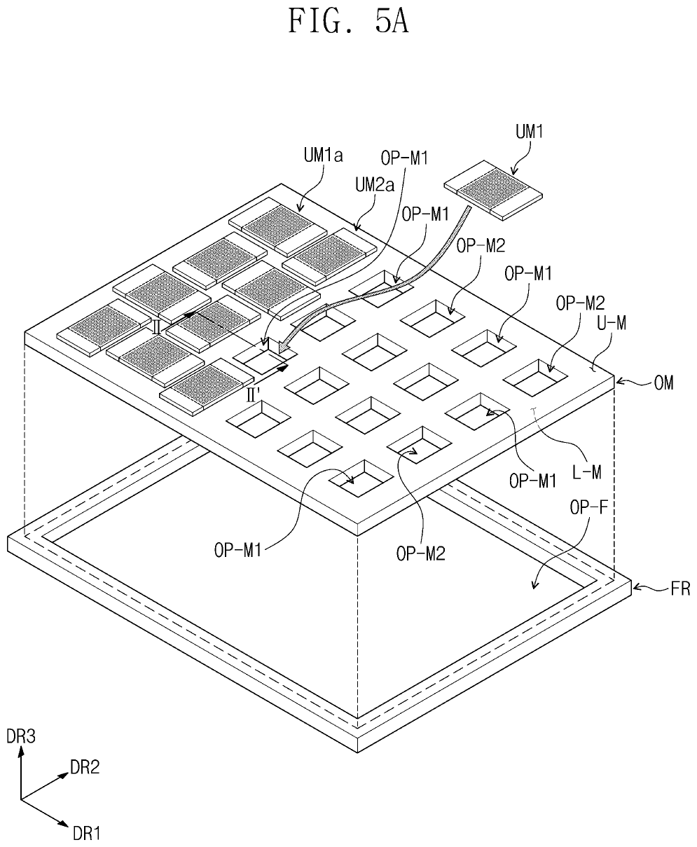

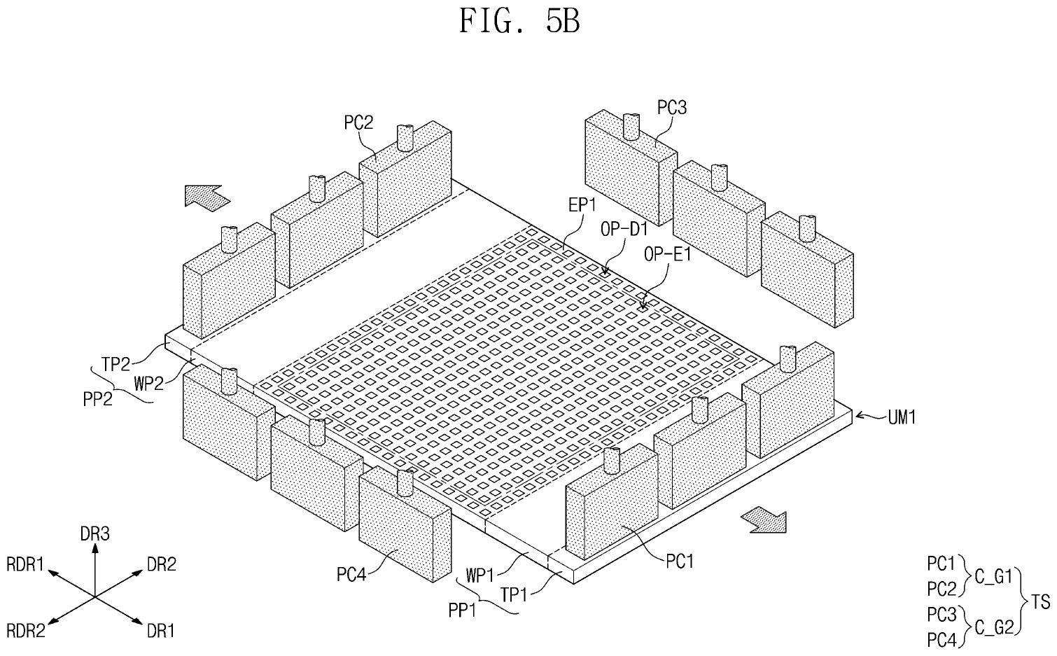

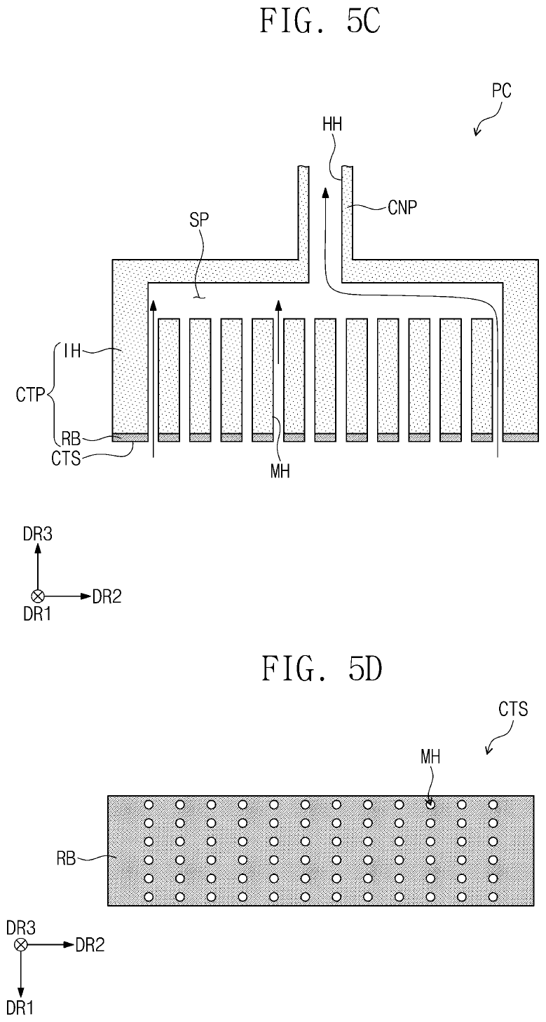

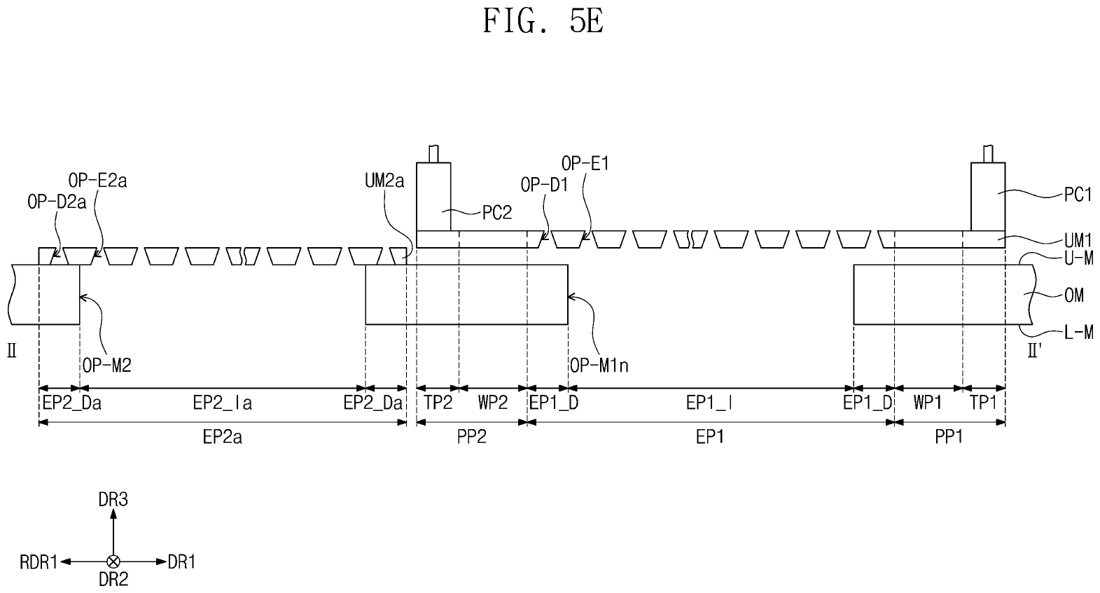

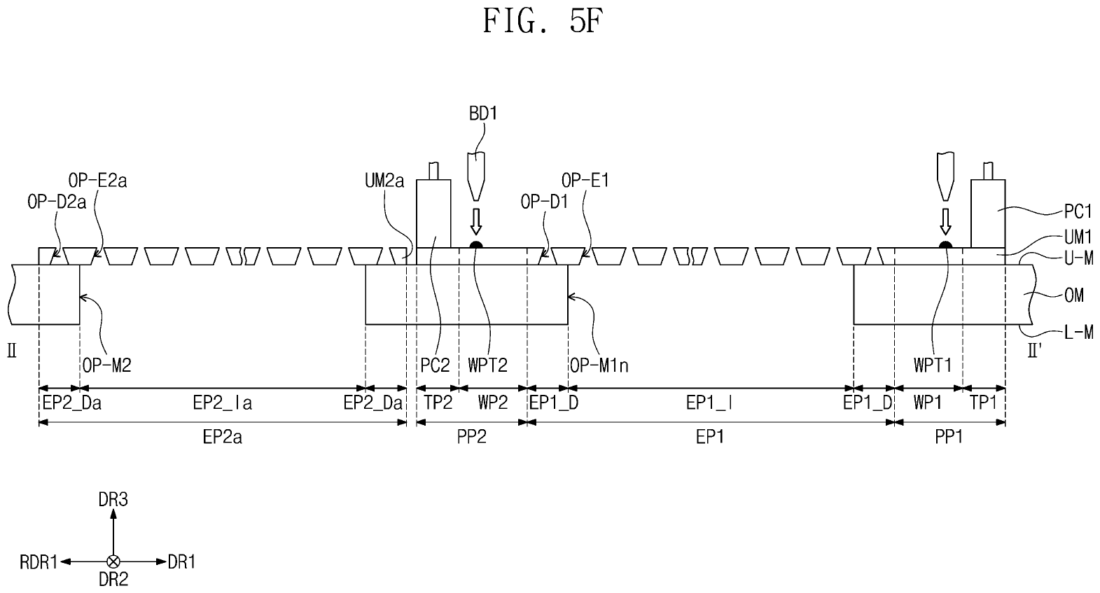

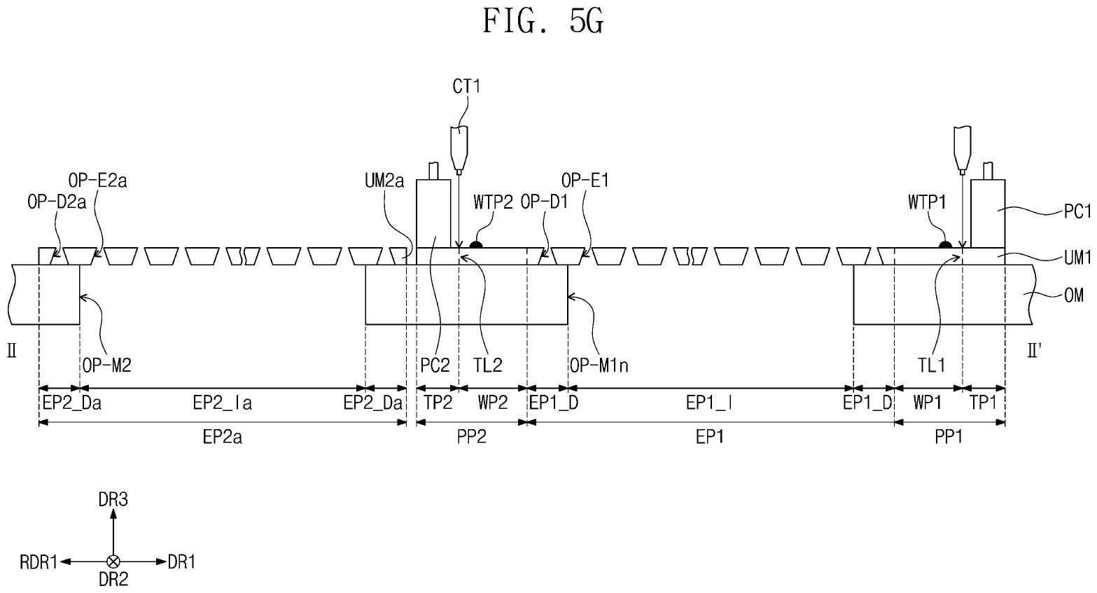

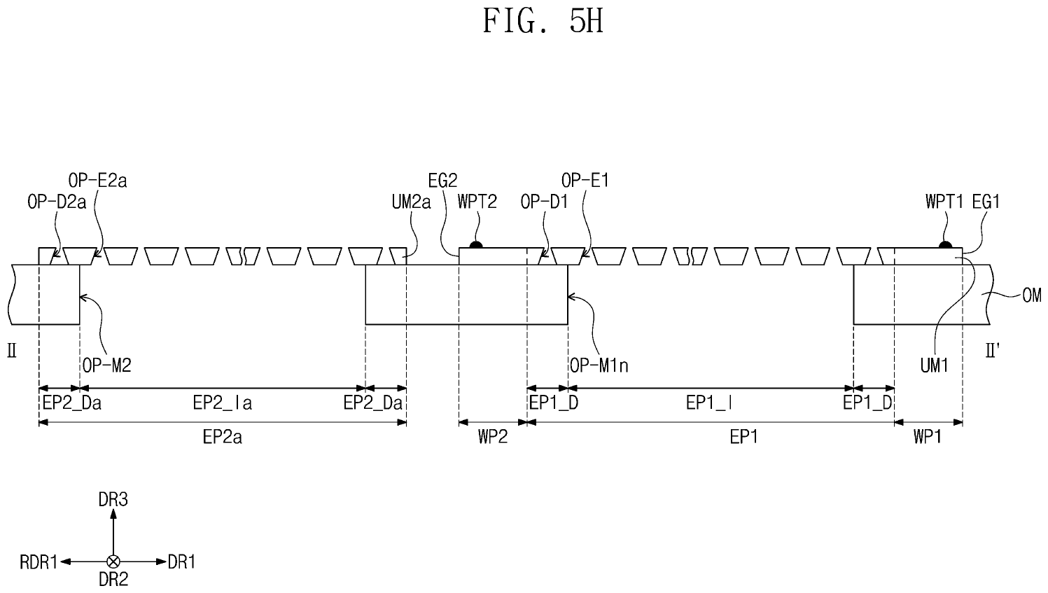

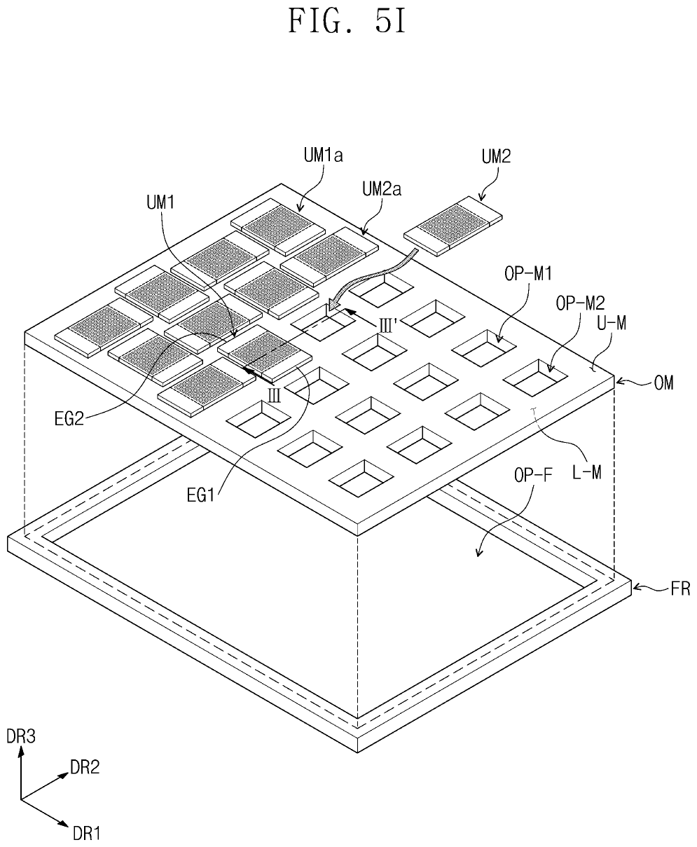

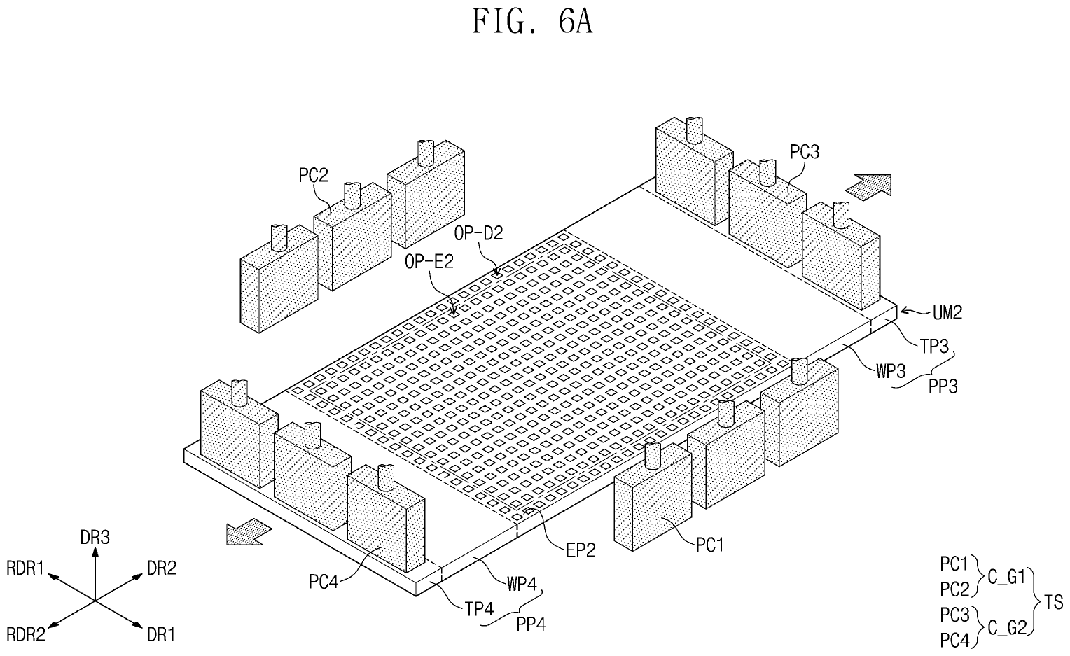

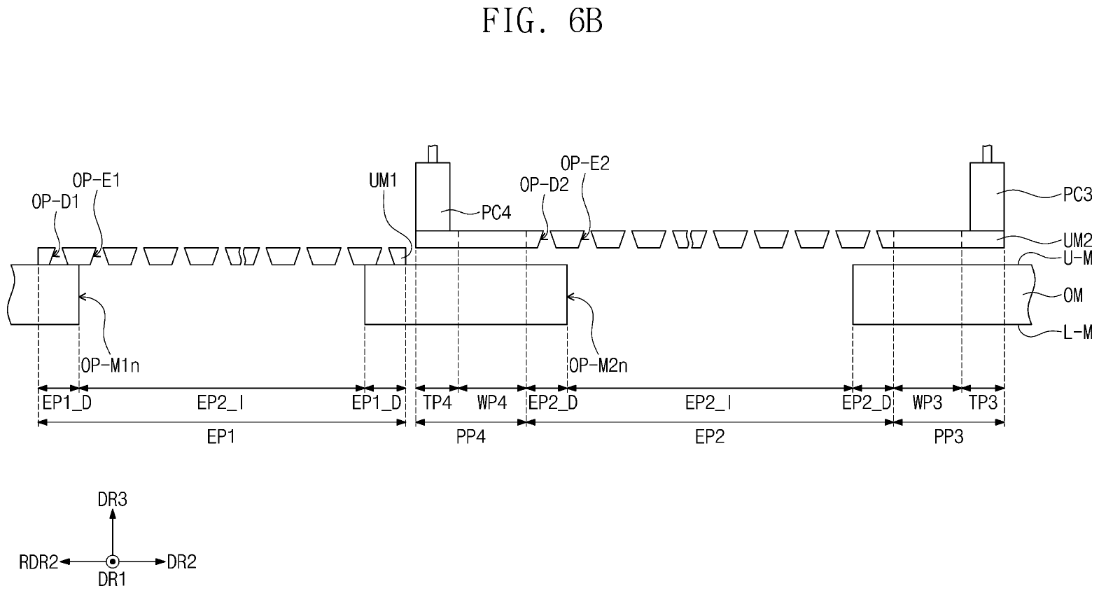

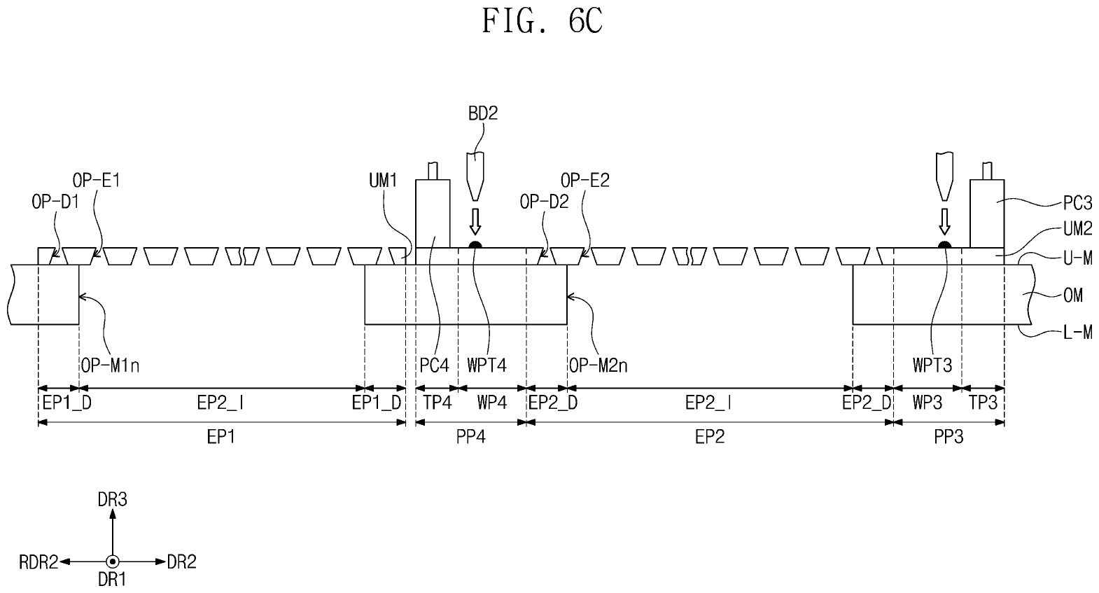

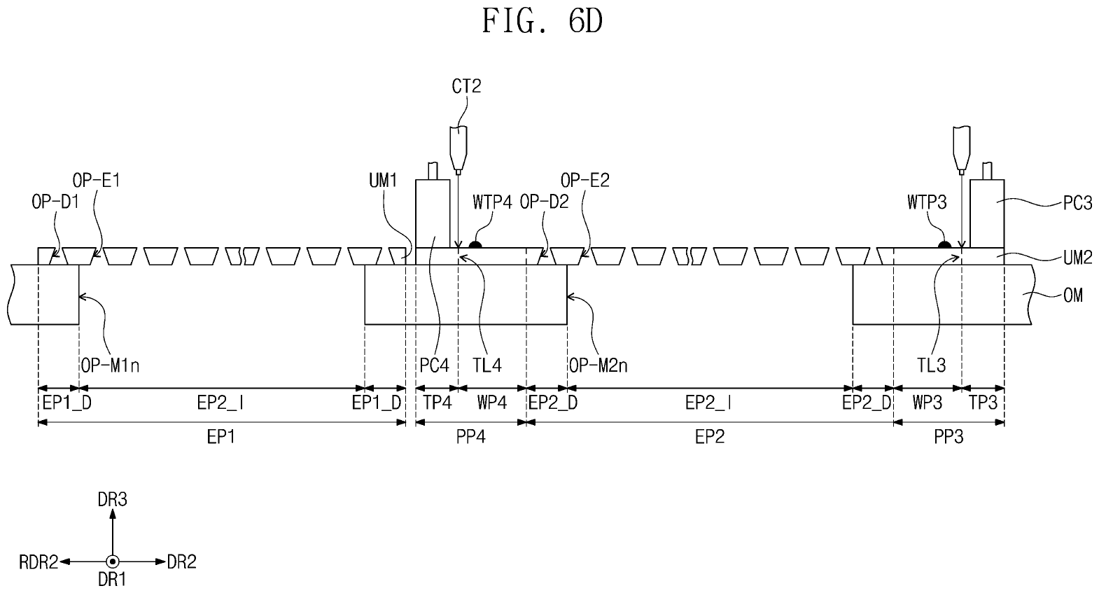

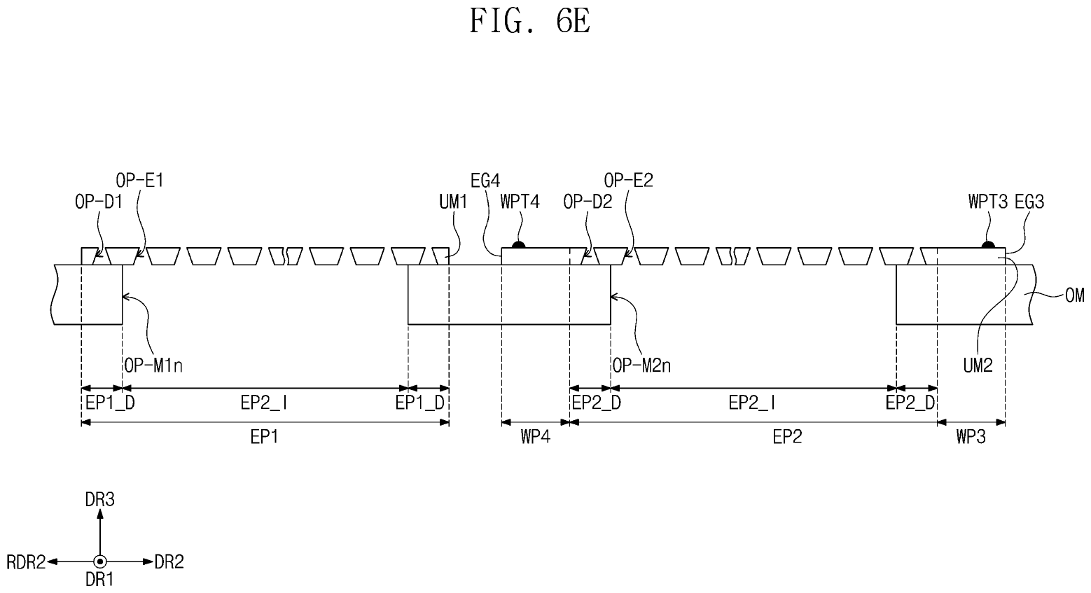

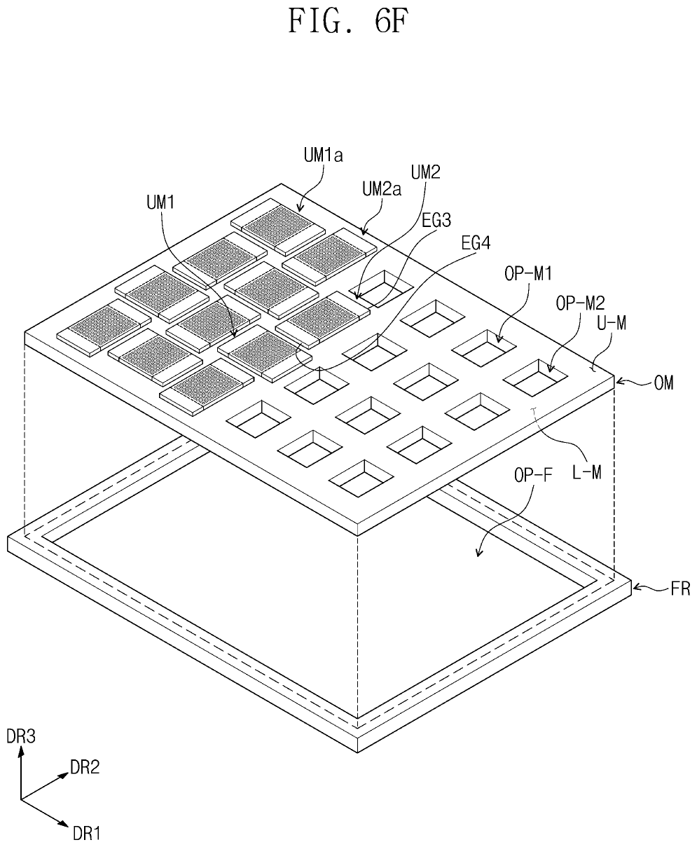

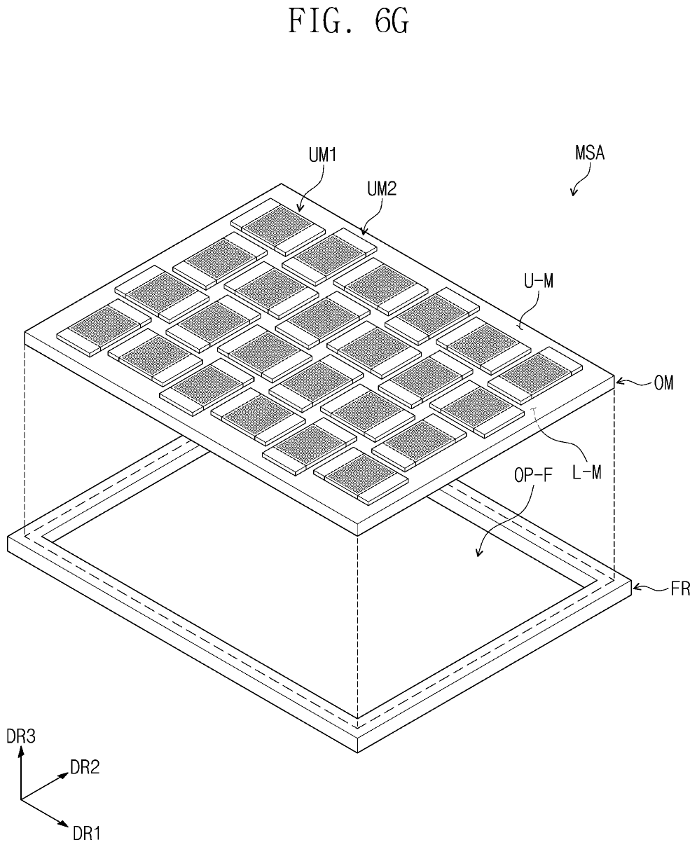

In detail, since the second unit mask UM2 is tensioned in the second direction DR2 and the second opposite direction RDR2, a portion for a tensioner TS (refer to FIG. 5B) to be disposed and/or a portion for a welding process may not be provided at a portion adjacent to the second deposition portion EP2 in the first direction DR1, and thus, a separate welding portion extending from the second deposition portion EP2 in the first direction DR1 and the first opposite direction RDR1 may not be provided. Accordingly, a space where the first unit mask UM1 is placed may be expanded in the space between the first and second open openings OP-M1 and OP-M2 adjacent to each other in the first direction DR1.

Accordingly, a minimum separation distance d1 from each of the first and second welding protrusions WPT1 and WPT2 to the first deposition openings OP-E1 through which the deposition material substantially passes may increase. Therefore, in case that the deposition pattern is formed in the base substrate BS (refer to FIG. 1) using the mask assembly MSA, the first and second welding protrusions WPT1 and WPT2 may be apart from the portion where the deposition pattern is formed, and thus, an adhesion between the portion where the deposition pattern is formed in the base substrate BS (refer to FIG. 1) and the first unit mask UM1 may increase.

Similarly, since the first unit mask UM1 is tensioned in the first direction DR1 and the first opposite direction RDR1, a portion for the tensioner TS (refer to FIG. 5B) to be disposed and/or a portion for a welding process may not be provided at a portion adjacent to the first deposition portion EP1 in the second direction DR2, and thus, a separate welding portion extending from the first deposition portion EP1 in the second direction DR2 and the first opposite direction RDR1 may not be provided. Accordingly, a space where the second unit mask UM2 is placed may be expanded in the space between the first and second open openings OP-M1 and OP-M2 adjacent to each other in the second direction DR2.

Accordingly, a minimum separation distance d2 from each of the third and fourth welding protrusions WPT3 and WPT4 to the second deposition openings OP-E2 through which the deposition material substantially passes may increase. Therefore, the third and fourth welding protrusions WPT3 and WPT4 may be apart from the portion where the deposition pattern is formed, and thus, an adhesion between the portion where the deposition pattern is formed in the base substrate BS (refer to FIG. 1) and the second unit mask UM2 may increase.

In a case where a space at which the mask assembly MSA is not in tight contact with the base substrate BS (refer to FIG. 1) is formed, a shadow area where the deposition material EM (refer to FIG. 1) is insufficiently deposited may occur in areas adjacent to the inner side surfaces of the first and second unit masks UM1 and UM2, which respectively define the first and second deposition openings OP-E1 and OP-E2. However, according to the disclosure, the adhesion between the first and second unit masks UM1 and UM2 and the base substrate BS (refer to FIG. 1) may increase, and thus the shadow area may be reduced. Accordingly, the precision of each of the deposition patterns may be improved, and a display quality of the display panel DP (refer to FIG. 7) may be improved.

According to an embodiment, the minimum separation distance d1 (hereinafter, referred to as a first minimum separation distance) from the first welding protrusions WPT1 to corresponding first deposition openings OP-E1 in plan view may be equal to or greater than about 7.5 mm. The display panel DP (refer to FIG. 7) to which the deposition pattern is formed may be a medium-sized display panel. In case that the first minimum separation distance d1 is smaller than about 7.5 mm, the adhesion between the first unit mask UM1 and the base substrate BS (refer to FIG. 1) may not be sufficient in the deposition process. As a result, the shadow area may occur, and the precision of the deposition patterns may be lowered.

In plan view, the minimum separation distance d2 (hereinafter, referred to as a second minimum separation distance) from the second welding protrusions WPT2 to the corresponding second deposition openings OP-E2 may also be equal to or greater than about 7.5 mm. The display panel DP (refer to FIG. 7) to which the deposition pattern is formed may be the medium-sized display panel. In case that the second minimum separation distance d2 is smaller than about 7.5 mm, the adhesion between the second unit mask UM2 and the base substrate BS (refer to FIG. 1) may not be sufficient in the deposition process. As a result, the shadow area may occur, and the precision of the deposition patterns may be lowered. However, the first minimum separation distance d1 and the second minimum separation distance d2 should not be particularly limited and may vary depending on the size of the display panel DP (refer to FIG. 7) to which the deposition pattern is formed.

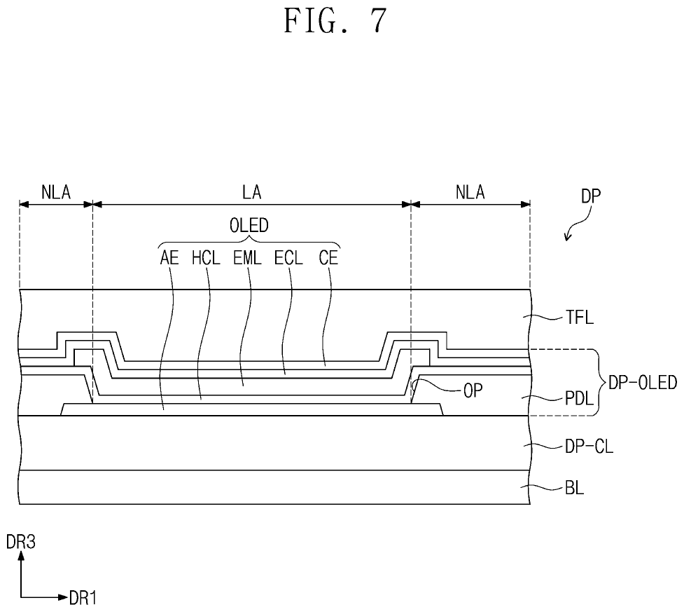

FIGS. 5A and 5B are schematic perspective views of a method of manufacturing the mask assembly according to an embodiment of the disclosure. FIG. 5C is an enlarged schematic cross-sectional view of the tensioner used to manufacture the mask assembly according to an embodiment of the disclosure. FIG. 5D is an enlarged schematic plan view of the tensioner used to manufacture the mask assembly according to an embodiment of the disclosure. FIGS. 5E to 5H are schematic cross-sectional views of the manufacturing method of the mask assembly according to an embodiment of the disclosure FIG. 51 is a schematic perspective view of the manufacturing method of the mask assembly according to an embodiment of the disclosure. FIGS. 5E to 5H are cross-sections taken along a line II-II′ of FIG. 5A.

FIG. 6A is a schematic perspective view of the manufacturing method of the mask assembly according to an embodiment of the disclosure. FIGS. 6B to 6E are schematic cross-sectional views of the manufacturing method of the mask assembly according to an embodiment of the disclosure. FIGS. 6F and 6G are schematic perspective views of the manufacturing method of the mask assembly according to an embodiment of the disclosure. FIGS. 6B to 6E are cross-sections taken along a line III-III′ of FIG. 5I.

The manufacturing method of the mask assembly may include providing the open mask through which the first and second open openings are defined, placing the first unit mask through which the first deposition openings are defined on the open mask to allow the first deposition openings to overlap the first open opening, coupling the first unit mask to the open mask, placing the second unit mask through which the second deposition openings are defined on the open mask to allow the second deposition openings to overlap the second open opening, and coupling the second unit mask to the open mask.

FIGS. 5A to 5I show processes to attach the first unit mask UM1 to the open mask OM, and FIGS. 6A to 6G show processes to attach the second unit mask UM2 to the open mask OM. In FIGS. 5A to 5I and 6A to 6G, the same/similar reference numerals denote the same/similar elements in FIGS. 1 to 4, and thus, detailed descriptions of the same/similar elements will be omitted.

Referring to FIG. 5A, the manufacturing method of the mask assembly may include the providing of the open mask OM through which the first open openings OP-M1 and the second open openings OP-M2 are defined. The first open openings OP-M1 and the second open openings OP-M2 may be alternately arranged with each other in the first direction DR1 and the second direction DR2.

For the convenience of explanation, FIG. 5A shows the open mask OM provided with first unit masks UM1a and second unit masks UM2a, which are previously attached to the open mask OM. Hereinafter, a method of attaching the first unit mask UM1 to be arranged to correspond to a first open opening OP-M1n arranged in a third row and a third column will be described with reference to FIGS. 5B to 5I, and a method of attaching a second unit mask UM2 to be arranged to correspond to a second open opening OP-M2n arranged in the third row and a second column will be described with reference to FIGS. 6A to 6G. However, the order of attachment of the first and second unit masks UM1 and UM2 should not be limited thereto or thereby.

Referring to FIGS. 5B to 5F, the manufacturing method of the mask assembly may include placing the first unit mask UM1 on the open mask OM. The placing of the first unit mask UM1 on the open mask OM may include tensioning the first unit mask UM1 (hereinafter, referred to as a first tensioning process) and aligning the first unit mask UM1 on the open mask OM (hereinafter, referred to as a first aligning process).

As shown in FIGS. 5B, 5E, and 5F, in the placing of the first unit mask UM1, which includes the first tensioning process and the first aligning process, the first unit mask UM1 may include the first deposition portion EP1, a first protruding portion PP1 extending from the first deposition portion EP1 to the first direction DR1, and a second protruding portion PP2 extending from the first deposition portion EP1 to the first opposite direction RDR1 opposite to the first direction DR1.

The first deposition portion EP1 may include the first deposition openings OP-E1 and the first deposition dummy openings OP-D1 surrounding the first deposition openings OP-E1. In an embodiment, the first deposition openings OP-E1 and the first deposition dummy openings OP-D1 may have substantially the same shape and size as each other. The first deposition dummy openings OP-D1 may be defined as openings placed outside the first deposition openings OP-E1 among the openings defined through the first deposition portion EP1.

FIG. 5B shows a structure in which the first deposition dummy openings OP-D1 are arranged in a line along the first deposition openings placed at an outer position among the first deposition openings OP-E1, however, the first deposition dummy openings OP-D1 may be arranged multiple lines. According to an embodiment, the first deposition dummy openings OP-D1 may be omitted, and the first deposition portion EP1 may include only the first deposition openings OP-E1.

The first protruding portion PP1 may include the first welding portion WP1 extending from the first deposition portion EP1 to the first direction DR1 and a first tension portion TP1 extending from the first welding portion WP1 to the first direction DR1. The first tension portion TP1 may be spaced apart from the first deposition portion EP1 with the first welding portion WP1 interposed therebetween.

The second protruding portion PP2 may include the second welding portion WP2 extending from the first deposition portion EP1 to the first opposite direction RDR1 and a second tension portion TP2 extending from the second welding portion WP2 to the first opposite direction RDR1. The second tension portion TP2 may be spaced apart from the first deposition portion EP1 with the second welding portion WP2 interposed therebetween.

Referring to FIG. 5B, the first unit mask UM1 may be tensioned to the first direction DR1 and the first opposite direction RDR1 in the first tensioning process. In an embodiment, the first unit mask UM1 may be tensioned using the tensioner TS in the first tensioning process. Hereinafter, the tensioner TS will be described in detail with reference to FIGS. 5B to 5D.

The tensioner TS may include a first group chuck C_G1 and a second group chuck C_G2.

The first group chuck C_G1 may include first porous chucks PC1 and second porous chucks PC2. The first porous chucks PC1 may be arranged in the second direction DR2, and the second porous chucks PC2 may be spaced apart from the first porous chucks PC1 in the first direction DR1 and may be arranged in the second direction DR2.

The second group chuck C_G2 may include third porous chucks PC3 and fourth porous chucks PC4. The third porous chucks PC3 may be arranged in the first direction DR1, and the fourth porous chucks PC4 may be spaced apart from the third porous chucks PC3 in the second direction DR2 and may be arranged in the first direction DR1.

The third porous chucks PC3 may be arranged adjacent to the first and second porous chucks placed at a right position among the first and second porous chucks PC1 and PC2, and the fourth porous chucks PC4 may be arranged adjacent to the first and second porous chucks placed at a left position among the first and second porous chucks PC1 and PC2.

FIG. 5B shows a structure in which the tensioner TS includes the multiple first porous chucks PC1, the multiple second porous chucks PC2, the multiple third porous chucks PC3, and the multiple fourth porous chucks PC4 as a representative example, however, the disclosure should not be limited thereto or thereby. According to an embodiment, the tensioner TS may include one first porous chuck PC1 and one second porous chuck PC2, which extend in the second direction DR2, and one third porous chuck PC3 and one fourth porous chuck PC4, which extend in the first direction DR1.

Referring to FIGS. 5C and 5D, each of the first, second, third, and fourth porous chucks PC1 and PC2, PC3, and PC4 (refer to FIG. 5B, hereinafter, referred to as a porous chuck PC) may include a coupling portion CTP and a connection portion CNP. The coupling portion CTP may be coupled with the first unit mask UM1 or the second unit mask UM2 (refer to FIG. 6A) and may include a contact surface CTS provided on a rear surface thereof and being in contact with the first unit mask UM1 or the second unit mask UM2 (refer to FIG. 6A). The connection portion CNP may be connected to the coupling portion CTP and may move the coupling portion CTP in one of the first direction DR1, the first opposite direction RDR1, the second direction DR2, and the second opposite direction RDR2.

The coupling portion CTP may include a body portion IH and a contact portion RB.

The body portion IH may be provided with multiple fine holes MH defined therethrough and an inner space SP defined therein. The inner space SP may be connected to a hole HH of the connection portion CNP. In case that a vacuum is generated using a controller (not shown), an air outside the porous chuck PC may be introduced through the fine holes MH and may flow to the hole HH through the inner space SP. Accordingly, the first unit mask UM1 or the second unit mask UM2 (refer to FIG. 6A) may be tightly adhered to the contact surface CTS and may be coupled with the porous chuck PC.

The contact portion RB may be provided with holes defined therethrough to correspond to the fine holes MH. The contact surface CTS of the porous chuck PC may be provided by the contact portion RB. The contact portion RB may be formed of a material with flexibility. As an example, the contact portion RB may include polymer or rubber. Accordingly, the first unit mask UM1 or the second unit mask UM2 (refer to FIG. 6A) that is in contact with the contact surface CTS may be prevented from being physically damaged.

In an embodiment, the tensioner TS may operate in one of a first mode and a second mode. The operation mode of the tensioner TS may be determined by a separate controller (not shown). The tensioner TS may operate in the first mode during the first tensioning process. The tensioner TS may operate in the second mode during a second tensioning process described later.

As shown in FIG. 5B, the first group chuck C_G1 of the tensioner TS may be disposed on the first unit mask UM1 in the first tensioning process. In detail, the first porous chucks PC1 of the tensioner TS may be disposed on the first tension portion TP1 to be in contact with the first tension portion TP1, and the second porous chucks PC2 may be disposed on the second tension portion TP2 to be in contact with the second tension portion TP2. The second group chuck C_G2 of the tensioner TS may be spaced apart from the first unit mask UM1.

As the first porous chucks PC1 move in the first direction DR1 and the second porous chucks PC2 move in the first opposite direction RDR1 during the first mode, the first unit mask UM1 may be tensioned in the direction to which the first protruding portion PP1 and the second protruding portion PP2 extend from the first deposition portion EP1, i.e., in the first direction DR1 and the first opposite direction RDR1.

Referring to FIG. 5E, the first unit mask UM1 may be aligned above the open mask OM in the first aligning process to allow the first deposition openings OP-E1 of the first unit mask UM1 to overlap the first open opening OP-M1n.

Referring to FIG. 5F, in the state where the first deposition openings OP-E1 overlap the corresponding first open opening OP-M1n, the first unit mask UM1 may be disposed on the upper surface U-M of the open mask OM. In case that the first unit mask UM1 is disposed on the upper surface U-M of the open mask OM, the first unit mask UM1 may be provided while being tensioned to the first direction DR1 and the first opposite direction RDR1

The method of aligning the first unit mask UM1 on the open mask OM after tensioning the first unit mask UM1 is shown in FIGS. 5B to 5F, however, the disclosure should not be limited thereto or thereby. According to an embodiment, the first unit mask UM1 may be tensioned after being aligned on the open mask OM, or the first unit mask UM1 may be aligned on the open mask OM while being tensioned at the same time. In case that the first unit mask UM1 is disposed on the upper surface U-M of the open mask OM, the first unit mask UM1 may be provided with tension applied to the first direction DR1 and the first opposite direction RDR1.

Referring to FIG. 5F, the manufacturing method of the mask assembly may include coupling the first unit mask UM1 to the open mask OM (hereinafter, referred to as a first welding process).

In the first welding process, the first unit mask UM1 may be coupled to the open mask OM using a first bonding device BD1. The first bonding device BD1 may be a welding machine or a laser oscillator. The first bonding device BD1 may provide a thermal beam or a laser beam to the first welding portion WP1 and the second welding portion WP2. A portion of the first unit mask UM1 may be melted, and thus, the open mask OM may be coupled to the first unit mask UM1.

After the welding process is performed on the first welding portion WP1, the first welding protrusions WPT1 may be formed on the first welding portion WP1, and after the welding process is performed on the second welding portion WP2, the second welding protrusions WPT2 may be formed on the second welding portion WP2.

Referring to FIG. 5G, the manufacturing method of the mask assembly may include cutting the first unit mask UM1 (hereinafter, referred to as a first trimming process).

In the first trimming process, the first tension portion TP1 and the second tension portion TP2 of the first unit mask UM1 may be cut using a first cutter CT1. The first cutter CT1 may irradiate a beam along a first trimming line TL1 and a second trimming line TL2 to cut the first unit mask UM1.

The first trimming line TL1 may be defined between a portion at which the first porous chuck PC1 of the tensioner TS (refer to FIG. 5B) is disposed and a portion at which the first welding protrusions WPT1 are disposed. The second trimming line TL2 may be defined between a portion at which the second porous chucks PC2 of the tensioner TS (refer to FIG. 5B) is disposed and a portion at which the second welding protrusions WPT2 are disposed. Each of the first and second trimming lines TL1 and TL2 may extend in the second direction DR2.

Various devices may be used as the first cutter CT1 as long as the devices provide the beam to the first unit mask UM1 to remove the first tension portion TP1 and the second tension portion TP2. As an example, the first cutter CT1 may include a heat irradiator, a light irradiator, a laser oscillator, and/or the like.

Both ends of the first unit mask UM1, which are cut in the first trimming process, may respectively correspond to the edge EG1 of the first welding portion WP1 spaced apart from the first deposition portion EP1 and the edge EG2 of the second welding portion WP2 spaced apart from the first deposition portion EP1. The ends of the first unit mask UM1 may be closer to the first welding protrusions WPT1 and the second welding protrusions WPT2, respectively, after being cut than before being cut.

Referring to FIGS. 5H and 5I, the cut first unit mask UM1 may include new both ends, and the new both ends may respectively correspond to the edge EG1 of the first welding portion WP1 spaced apart from the first deposition portion EP1 and the edge EG2 of the second welding portion WP2 spaced apart from the first deposition portion EP1. The new both ends of the cut first unit mask UM1 may be closer to the first welding protrusions WPT1 and the second welding protrusions WPT2, respectively, than the both ends of the first unit mask UM1 before being cut.

The first protruding portion PP1 (refer to FIG. 5E) of the cut first unit mask UM1 may correspond to the first welding portion WP1, and the second protruding portion PP2 (refer to FIG. 5E) of the cut first unit mask UM1 may correspond to the second welding portion WP2. The first unit mask UM1 included in the mask assembly MSA (refer to FIG. 6G) that is completely manufactured may include only the first deposition portion EP1, the first welding portion WP1, and the second welding portion WP2.

FIGS. 5E to 5H show the open mask OM to which the second unit mask UM2a is previously attached as shown in FIG. 5A, and components of the previously attached second unit mask UM2a are assigned with reference numerals with ‘a’. Details on the components of the second unit mask UM2 described with reference to FIGS. 2 to 4 may be equally applied to the previously attached second unit mask UM2a.

As shown in FIGS. 5E to 5H, as the first unit mask UM1 is arranged to be aligned with the previously attached second unit mask UM2a in the first direction DR1, the welding portions of the previously attached second unit mask UM2a may not be disposed in the space between the first open opening OP-M1n and the second open opening OP-M2 of the open mask OM, and only the second protruding portion PP2 of the first unit mask UM1 may be disposed in the space between the first open opening OP-M1n and the second open opening OP-M2 of the open mask OM.

Accordingly, the area of the portion where the second protruding portion PP2 is placed may be relatively large, and the second welding protrusion WPT2 formed on the second welding portion WP2 may be placed relatively apart from the first deposition openings OP-E1. Therefore, the adhesion between the portion of the first unit mask UM1 adjacent to the first deposition openings OP-E1 and the base substrate BS (refer to FIG. 1) may increase in the deposition process, and the shadow area may be reduced. Thus, the precision of the deposition patterns may be improved.

Referring to FIGS. 6A to 6C, the manufacturing method of the mask assembly may include placing the second unit mask UM2 on the open mask OM. The placing of the second unit mask UM2 on the open mask OM may include tensioning the second unit mask UM2 (hereinafter, referred to as a second tensioning process) and aligning the second unit mask UM2 on the open mask OM (hereinafter, referred to as a second aligning process).

Referring to FIGS. 6A to 6C, in the placing of the second unit mask UM2, which includes the second tensioning process and the second aligning process, the second unit mask UM2 may include the second deposition portion EP2, a third protruding portion PP3 extending from the second deposition portion EP2 to the second direction DR2, and a fourth protruding portion PP4 extending from the second deposition portion EP2 to the direction opposite to the second direction DR2, i.e., the second opposite direction RDR2.

The second deposition portion EP2 may include the second deposition openings OP-E2 and the second deposition dummy openings OP-D2 surrounding the second deposition openings OP-E2. In an embodiment, the second deposition openings OP-E2 and the second deposition dummy openings OP-D2 may have substantially the same shape and size as each other. The second deposition dummy openings OP-D2 may be defined as openings disposed at an outer side of the second deposition openings OP-E2 among the openings defined through the second deposition portion EP2.

FIG. 6B shows a structure in which the second deposition dummy openings OP-D2 are arranged in a line along an arrangement of the second deposition openings arranged at an outer position among the second deposition openings OP-E2 as a representative example, however, according to an embodiment, the second deposition dummy openings OP-D2 may be arranged in multiple of lines. According to an embodiment, the second deposition dummy openings OP-D2 may be omitted, and the second deposition portion EP2 may include only the second deposition openings OP-E2.

The third protruding portion PP3 may include the third welding portion WP3 extending from the second deposition portion EP2 to the second direction DR2 and a third tension portion TP3 extending from the third welding portion WP3 to the second direction DR2. The third tension portion TP3 may be spaced apart from the second deposition portion EP2 with the third welding portion WP3 interposed therebetween.

The fourth protruding portion PP4 may include the fourth welding portion WP4 extending form the second deposition portion EP2 to the second opposite direction RDR2 and a fourth tension portion TP4 extending from the fourth welding portion WP4 to the second opposite direction RDR2. The fourth tension portion TP4 may be spaced apart from the second deposition portion EP2 with the fourth welding portion WP4 interposed therebetween.

Referring to FIG. 6A, the second unit mask UM2 may be tensioned in the second direction DR2 and the second opposite direction RDR2 during the second tensioning process. In an embodiment, the second unit mask UM2 may be tensioned using the tensioner TS during the second tensioning process. As described above, the tensioner TS may operate in the second mode during the second tensioning process.

The second group chuck C_G2 of the tensioner TS may be disposed on the second unit mask UM2 in the second tensioning process. In detail, the third porous chucks PC3 of the tensioner TS may be disposed on the third tension portion TP3 and may be in contact with the third tension portion TP3, and the fourth porous chucks PC4 may be disposed on the fourth tension portion TP4 and may be in contact with the fourth tension portion TP4. The first group chuck C_G1 of the tensioner TS may be spaced apart from the second unit mask UM2.

As the third porous chucks PC3 move in the second direction DR2 and the fourth porous chucks PC4 move in the second opposite direction RDR2 in the second mode, the second unit mask UM2 may be tensioned in the direction to which the third protruding portion PP3 and the fourth protruding portion PP4 extend from the second deposition portion EP2, i.e., in the second direction DR2 and the second opposite direction RDR2.

Referring to FIG. 6B, the second unit mask UM2 may be aligned on the open mask OM in the second aligning process to allow the second deposition openings OP-E2 of the second unit mask UM2 to overlap the second open opening OP-M2n.

Referring to FIG. 6C, the second unit mask UM2 may be disposed on the upper surface U-M of the open mask OM in a state in which the second deposition openings OP-E2 overlap the corresponding second open opening OP-M2n. In case that the second unit mask UM2 is disposed on the upper surface U-M of the open mask OM, the second unit mask UM2 may be provided with tension applied to the second direction DR2 and the second opposite direction RDR2.

The method of aligning the second unit mask UM2 on the open mask OM after tensioning the second unit mask UM2 is shown in FIGS. 6A to 6C, however, the disclosure should not be limited thereto or thereby. According to an embodiment, the second unit mask UM2 may be tensioned after being aligned on the open mask OM, or the second unit mask UM2 may be aligned on the open mask OM while being tensioned at the same time. In case that the second unit mask UM2 is disposed on the upper surface U-M of the open mask OM, the second unit mask UM2 may be provided with tension applied to the second direction DR2 and the second opposite direction RDR2.

Referring to FIG. 6C, the manufacturing method of the mask assembly may include coupling the second unit mask UM2 to the open mask OM (hereinafter, referred to as a second welding process).

In the second welding process, the second unit mask UM2 may be coupled to the open mask OM using a second bonding device BD2. The second bonding device BD2 may be a welding machine or a laser oscillator. The second bonding device BD2 may provide a thermal beam or a laser beam to the third welding portion WP3 and the fourth welding portion WP4. A portion of the second unit mask UM2 may be melted, and thus, the open mask OM may be coupled to the second unit mask UM2.

After the welding process is performed on the third welding portion WP3, the third welding protrusions WPT3 may be formed on the third welding portion WP3, and after the welding process is performed on the fourth welding portion WP4, the fourth welding protrusions WPT4 may be formed on the fourth welding portion WP4.

Referring to FIG. 6D, the manufacturing method of the mask assembly may include cutting the second unit mask UM2 (hereinafter, referred to as a second trimming process).

In the second trimming process, the third tension portion TP3 and the fourth tension portion TP4 of the second unit mask UM2 may be cut using a second cutter CT2. The second cutter CT2 may irradiate a beam along a third trimming line TL3 and a fourth trimming line TL4 to cut the second unit mask UM2.

The third trimming line TL3 may be defined between a portion at which the third porous chuck PC3 of the tensioner TS (refer to FIG. 6A) is disposed and a portion at which the third welding protrusions WPT3 are disposed. The fourth trimming line TL4 may be defined between a portion at which the fourth porous chucks PC4 of the tensioner TS (refer to FIG. 6A) is disposed and a portion at which the fourth welding protrusions WPT4 are disposed. Each of the third and fourth trimming lines TL3 and TL4 may extend in the first direction DR1.

Various devices may be used as the second cutter CT2 as long as the devices provide the beam to the second unit mask UM2 to remove the third tension portion TP3 and the fourth tension portion TP4. As an example, the second cutter CT2 may include a heat irradiator, a light irradiator, a laser oscillator, and the like.

Referring to FIGS. 6E and 6F, the cut second unit mask UM2 may include new both ends, and the new ends may respectively correspond to the edge EG3 of the third welding portion WP3 spaced apart from the second deposition portion EP2 and the edge EG4 of the fourth welding portion WP4 spaced apart from the second deposition portion EP2. The new ends of the second unit mask UM2 may be closer to the third welding protrusions WPT3 and the fourth welding protrusions WPT4, respectively, after being cut than before being cut.

The third protruding portion PP3 (refer to FIG. 6D) of the cut second unit mask UM2 may correspond to the third welding portion WP3, and the fourth protruding portion PP4 (refer to FIG. 5D) of the cut second unit mask UM2 may correspond to the fourth welding portion WP4. The second unit mask UM2 included in the mask assembly MSA (refer to FIG. 6G) that is completely manufactured may include only the second deposition portion EP2, the third welding portion WP3, and the fourth welding portion WP4.

FIGS. 6B to 6E show the second unit mask UM2 together with the first unit mask UM1 described with reference to FIGS. 5A to 5I. As shown in FIGS. 6B to 6E, as the second unit mask UM2 is arranged to be aligned with the first unit mask UM1 in the second direction DR2, the welding portions of the first unit mask UM1 may not be disposed in the space between the first open opening OP-M1n and the second open opening OP-M2n of the open mask OM, and only the fourth protruding portion PP4 of the second unit mask UM2 may be disposed in the space between the first open opening OP-M1n and the second open opening OP-M2n of the open mask OM.

Accordingly, the area of the portion where the fourth protruding portion PP4 is placed may be relatively large, and the fourth welding protrusion WPT4 formed on the fourth welding portion WP4 may be placed relatively apart from the second deposition openings OP-E2. Therefore, the adhesion between the portion of the second unit mask UM2 adjacent to the second deposition openings OP-E2 and the base substrate BS (refer to FIG. 1) may increase in the deposition process, and the shadow area may be reduced. Thus, the precision of the deposition patterns may be improved.

The first trimming process shown in FIG. 5G and the second trimming process shown in FIG. 6D may be omitted. According to an embodiment, the portion of the first unit mask UM1 on which the porous chucks PC1 and PC2 are disposed may not be removed, and the completely manufactured mask assembly MSA (refer to FIG. 6G) may be provided with the portion of the first unit mask UM1 on which the porous chucks PC1 and PC2 are disposed. The first unit mask UM1 of the completely manufactured mask assembly MSA (refer to FIG. 6G) may include the first deposition portion EP1, the first welding portion WP1, the first tension portion TP1, the second welding portion WP2, and the second tension portion TP2. Similarly, the completely manufactured mask assembly MSA (refer to FIG. 6G) may be provided with the portion of the second unit mask UM2 on which the porous chucks PC3 and PC4 are disposed.

As the processes of attaching the first unit mask UM1 to the open mask OM shown in FIGS. 5A to 5I and the processes of attaching the second unit mask UM2 to the open mask OM shown in FIGS. 6A to 6F are repeatedly performed, the first unit masks UM1 may be attached to respectively correspond to the first open openings OP-M1 (refer to FIG. 5A) of the open mask OM shown in FIG. 5A, and the second unit masks UM2 may be attached to respectively correspond to the second open openings OP-M2 (refer to FIG. 5A) of the open mask OM shown in FIG. 5A. Accordingly, the mask assembly MSA shown in FIG. 6G may be manufactured. The completely manufactured mask assembly MSA may include the first unit masks UM1 and the second unit masks UM2, which are alternately arranged in the first direction DR1 and the second direction DR2.

FIG. 7 is a schematic cross-sectional view of the display panel DP according to an embodiment of the disclosure.

In an embodiment, the display panel DP may be a light emitting type display panel. The display panel DP may be one of an inorganic light emitting display panel and an organic light emitting display panel, and it should not be particularly limited.

The display panel DP may include a base layer BL, a circuit element layer DP-CL disposed on the base layer BL, a display element layer DP-OLED disposed on the circuit element layer DP-CL, and an encapsulation layer TFL disposed on the display element layer DP-OLED.

The base layer BL may be a glass substrate, a metal substrate, and/or a polymer substrate, however, it should not be limited thereto or thereby. The base layer BL may include an inorganic layer, an organic layer, or a composite material layer.

The circuit element layer DP-CL may include at least one insulating layer and a circuit element. The circuit element may include a signal line and a driving circuit of a pixel. The circuit element layer DP-CL may be formed by forming an insulating layer, a semiconductor layer, and a conductive layer using a coating or depositing process and patterning the insulating layer, the semiconductor layer, and the conductive layer using a photolithography process.

The display element layer DP-OLED may include a pixel definition layer PDL and a light emitting element OLED. The light emitting element OLED may be an organic light emitting diode or a quantum dot light emitting diode.

A first electrode AE may be disposed on the circuit element layer DP-CL. The pixel definition layer PDL may be provided with a light emitting opening OP defined therethrough to expose at least a portion of the first electrode AE. The light emitting opening OP of the pixel definition layer PDL may define a light emitting area LA. A non-light-emitting area NLA may surround the light emitting area LA.

A hole control layer HCL, an electron control layer ECL, and a second electrode CE may be commonly disposed in the light emitting area LA and the non-light-emitting area NLA. The hole control layer HCL and the electron control layer ECL may be commonly formed over multiple pixels using a mask different from the mask assembly MSA (refer to FIG. 2).

A light emitting layer EML may be patterned to correspond to the light emitting opening OP. The light emitting layer EML having a predetermined or selected shape may be formed using the mask assembly MSA (refer to FIG. 2) described above. However, the disclosure should not be limited thereto or thereby, and any component of the display panel DP that may be deposited through the mask assembly MSA (refer to FIG. 1) may be formed using the deposition apparatus EDA (refer to FIG. 1).

In case that the light emitting layer EML is deposited using the mask assembly MSA (refer to FIG. 2), the adhesion between base substrate BS and the first and second unit masks UM1 and UM2 (refer to FIG. 2) may increase, and thus, the deposition precision is improved. Accordingly, a display quality of the display panel DP may be improved.

The encapsulation layer TFL may be disposed on the light emitting element OLED. The encapsulation layer TFL may include multiple thin layers. The thin layers may include an inorganic layer and an organic layer. The encapsulation layer TFL may include an insulating layer to encapsulate the display element layer DP-OLED and an insulating layer to improve a light emission efficiency.

Although embodiments of the disclosure have been described, it is understood that the disclosure should not be limited to these embodiments but various changes and modifications can be made by one of ordinary skill in the art within the spirit and scope of the disclosure. Therefore, the disclosed subject matter should not be limited to any single embodiment described herein.

What is claimed is:

1. A mask assembly, comprising:
an open mask including first open openings and second open openings, which are defined through the open mask and alternately arranged in a first direction;
first unit masks respectively corresponding to the first open openings; and
second unit masks respectively corresponding to the second open openings, wherein
each of the first unit masks includes:
a first deposition portion including first deposition openings defined therethrough to overlap a corresponding first open opening among the first open openings;
a first welding portion extending from the first deposition portion to the first direction and coupled with the open mask; and
a second welding portion extending from the first deposition portion to a direction opposite to the first direction and coupled with the open mask, and each of the second unit masks includes:
a second deposition portion including second deposition openings defined therethrough to overlap a corresponding second open opening among the second open openings;
a third welding portion extending from the second deposition portion to a second direction perpendicular to the first direction and coupled with the open mask; and
a fourth welding portion extending from the second deposition portion to a direction opposite to the second direction and coupled with the open mask.

2. The mask assembly of claim 1, wherein each of the first welding portion and the second welding portion does not overlap the third welding portion and the fourth welding portion when viewed in the first direction.

3. The mask assembly of claim 1, wherein a length in the first direction of each of the first unit masks is greater than a length in the first direction of each of the second unit masks.

4. The mask assembly of claim 1, wherein a length in the second direction of each of the second unit masks is greater than a length in the second direction of each of the first unit masks.

5. The mask assembly of claim 1, wherein the first open openings and the second open openings are alternately arranged with each other in the second direction.

6. The mask assembly of claim 5, wherein each of the third and fourth welding portions does not overlap the first and second welding portions when viewed in the second direction.

7. The mask assembly of claim 1, further comprising:
first welding protrusions arranged on the first welding portion of each of the first unit masks in the second direction;
second welding protrusions arranged on the second welding portion of each of the first unit masks in the second direction;
third welding protrusions arranged on the third welding portion of each of the second unit masks in the first direction; and
fourth welding protrusions arranged on the fourth welding portion of each of the second unit masks in the first direction.

8. The mask assembly of claim 7, wherein a minimum separation distance between the first welding protrusions and the first deposition openings in one first unit mask among the first unit masks is equal to or greater than about 7.5 mm in plan view.

9. The mask assembly of claim 7, wherein a minimum separation distance between the third welding protrusions and the second deposition openings in one second unit mask among the second unit masks is equal to or greater than about 7.5 mm in plan view.

10. The mask assembly of claim 7, wherein
one of the first and second welding protrusions is disposed between the first and second open openings adjacent to each other in the first direction among the first and second open openings in plan view, and
one of the third and fourth welding protrusions is disposed between the first and second open openings adjacent to each other in the second direction among the first and second open openings in plan view.

11. The mask assembly of claim 1, wherein the first open openings and the second open openings include a same shape as each other.

12. The mask assembly of claim 1, wherein the first deposition portion of each of the first unit masks includes dummy deposition openings defined therethrough to overlap the open mask and surrounding the first deposition openings.

13. A method of manufacturing a mask assembly, comprising:
providing an open mask through which first and second open openings are defined;
placing a first unit mask through which first deposition openings are defined on the open mask to allow the first deposition openings to overlap the first open opening;
coupling the first unit mask with the open mask;
placing a second unit mask through which second deposition openings are defined on the open mask to allow the second deposition openings to overlap the second open opening; and
coupling the second unit mask with the open mask, wherein
the first unit mask is tensioned in a first direction and a direction opposite to the first direction in the placing of the first unit mask, and
the second unit mask is tensioned in a second direction perpendicular to the first direction and a direction opposite to the second direction in the placing of the second unit mask.

14. The method of claim 13, wherein
the first unit mask is tensioned using a tensioner operated in a first mode in the placing of the first unit mask, and
the second unit mask is tensioned using the tensioner operated in a second mode in the placing of the second unit mask.

15. The method of claim 14, wherein
the tensioner comprises:
a first group chuck comprising first porous chucks arranged in the second direction and second porous chucks spaced apart from the first porous chucks in the first direction and arranged in the second direction; and
a second group chuck comprising third porous chucks arranged in the first direction and fourth porous chucks spaced apart from the third porous chucks in the second direction and arranged in the first direction,
the first group chuck is in contact with the first unit mask to operate in the first mode, and
the second group chuck is in contact with the second unit mask to operate in the second mode.

16. The method of claim 15, wherein
the second group chuck is spaced apart from the first unit mask in the first mode, and
the first group chuck is spaced apart from the second unit mask in the second mode.

17. The method of claim 14, wherein
in the placing of the first unit mask, the first unit mask comprises:
a first deposition portion comprising the first deposition openings;
a first protruding portion comprising a first welding portion extending from the first deposition portion to the first direction and a first tension portion extending from the first welding portion to the first direction; and
a second protruding portion comprising a second welding portion extending from the first deposition portion to the direction opposite to the first direction and a second tension portion extending from the second welding portion to the direction opposite to the first direction, and
the tensioner is disposed on the first and second tension portions.

18. The method of claim 17, wherein, in the coupling of the first unit mask
first welding protrusions arranged in the second direction are formed on the first welding portion, and
second welding protrusions arranged in the second direction are formed on the second welding portion.

19. The method of claim 17, further comprising:
cutting the first unit mask to remove the first and second tension portions after the coupling of the first unit mask and before the placing of the second unit mask.

20. The method of claim 13, wherein each of the first and second open openings is provided in plural, and the plurality of first open openings are alternately arranged with the plurality of second open openings in each of the first and second directions.
